(19) United States
(12) Patent Application Publication
(10) Pub. No.: US 2026/0135482 A1
(43) Pub. Date: May 14, 2026

(54) VOLTAGE GENERATION CIRCUIT, MEMORY DEVICE, AND MEMORY SYSTEM

(71) Applicant: YANGTZE MEMORY TECHNOLOGIES CO., LTD., Wuhan (CN)

(72) Inventors: Zhuangzhuang WU, Wuhan (CN); Yiqun CEN, Wuhan (CN); Ruxin WEI, Wuhan (CN)

(21) Appl. No.: 19/013,883

(22) Filed: Jan. 8, 2025

(30) Foreign Application Priority Data
Aug. 26, 2024 (CN) 2024111791698

(51) Int. Cl. H02M 3/07; G11C 16/04; G11C 16/30; H02M 1/00

(52) U.S. Cl. CPC H02M 3/073; G11C 16/0483; G11C 16/30; H02M 1/0045

(57) ABSTRACT

The present disclosure provides a voltage generation circuit, a memory device and a memory system, and relates to the field of memory technology. The voltage generation circuit includes a clock voltage doubling circuit and a charge pump circuit, wherein the clock voltage doubling circuit includes a first signal generation circuit, a second signal generation circuit and a first output circuit; the first signal generation circuit is configured to apply a positive voltage signal to a first electrode of a MOS transistor in the first output circuit and apply a source voltage signal to a second electrode of the MOS transistor in the first output circuit under the control of an input first clock signal; the second signal generation circuit is configured to apply a second clock signal to a third electrode of the MOS transistor in the first output circuit under the control of the input first clock signal; the second clock signal is different from the first clock signal; and the first output circuit is configured to output a voltage doubling clock signal to the charge pump circuit under the control of the second clock signal.

### CROSS-REFERENCE TO RELATED APPLICATIONS

The present application claims priority to Chinese Patent Application No. 2024111791698, which was filed Aug. 26, 2024, and is hereby incorporated herein by reference in its entirety.

### TECHNICAL FIELD

The present disclosure relates to the field of memory technology, and particularly to a voltage generation circuit, a memory device and a memory system.

### BACKGROUND

In memory products such as a NAND, a clock voltage doubling circuit is usually configured to provide a voltage doubling clock signal to a charge pump circuit.

### SUMMARY

The present disclosure provides a voltage generation circuit, a memory device and a memory system, and can increase a voltage value of a high level of a voltage doubling clock signal output by a clock voltage doubling circuit. The technical solutions are as follows:

In an aspect, provided is a voltage generation circuit which comprises a clock voltage doubling circuit and a charge pump circuit, wherein the clock voltage doubling circuit comprises a first signal generation circuit, a second signal generation circuit and a first output circuit; the first signal generation circuit is connected with a first electrode and a second electrode of a metal oxide semiconductor (MOS) transistor in the first output circuit, the second signal generation circuit is connected with a third electrode of the MOS transistor in the first output circuit, and the second electrode of the MOS transistor in the first output circuit is connected with the charge pump circuit. The first signal generation circuit is configured to apply a positive voltage signal to the first electrode of the MOS transistor in the first output circuit and apply a source voltage signal to the second electrode of the MOS transistor in the first output circuit under the control of an input first clock signal. The second signal generation circuit is configured to apply a second clock signal different from the first clock signal to the third electrode of the MOS transistor in the first output circuit under the control of the input first clock signal. The first output circuit is configured to output a voltage doubling clock signal to the charge pump circuit under the control of the second clock signal.

In an optional example, a high level voltage of the voltage doubling clock signal is the same as a voltage of the positive voltage signal, and a low level voltage of the voltage doubling clock signal is the same as a voltage of the source voltage signal.

In an optional example, a first port of the first signal generation circuit is connected with the first electrode of the MOS transistor in the first output circuit, and a second port of the first signal generation circuit is connected with the second electrode of the MOS transistor in the first output circuit. The MOS transistor in the first output circuit is configured to output a high level voltage of the voltage doubling clock signal through the second electrode of the MOS transistor in the first output circuit when the second clock signal applied to the third electrode of the MOS transistor in the first output circuit is at a low level; and the MOS transistor in the first output circuit is configured to output a low level voltage of the voltage doubling clock signal through the second electrode of the MOS transistor in the first output circuit when the second clock signal applied to the third electrode of the MOS transistor in the first output circuit is at a high level, wherein a voltage of the second clock signal at the low level is greater than a voltage of the source voltage signal.

In an optional example, the first output circuit comprises a first MOS transistor and a second MOS transistor; the second clock signal comprises a first clock sub-signal and a second clock sub-signal; and the second signal generation circuit is configured to apply the first clock sub-signal to a third electrode of the first MOS transistor and apply the second clock sub-signal to a gate of the second MOS transistor, wherein the first clock sub-signal and the second clock sub-signal are the same in cycle, and level states of the first clock sub-signal and the second clock sub-signal at the same instant are opposite.

In an optional example, the second signal generation circuit comprises a low voltage generation sub-circuit and a clock signal generation sub-circuit, wherein the low voltage generation sub-circuit takes the source voltage signal as an input to output a voltage signal with a voltage amplitude greater than that of the source voltage signal to the clock signal generation sub-circuit; and the clock signal generation sub-circuit is configured to take positive voltage sources of the low voltage generation sub-circuit and a voltage conversion circuit as input sources to output the first clock sub-signal and the second clock sub-signal.

In an optional example, the low voltage generation sub-circuit comprises a third MOS transistor that is triggered to be turned on by a high level, wherein a first electrode and a third electrode of the third MOS transistor are connected with an output end of the third transistor, and a second electrode of the third MOS transistor is connected with a signal source of the source voltage signal; and a threshold voltage of the third MOS transistor is less than a voltage of the source voltage signal.

In an optional example, the low voltage generation sub-circuit is a linear regulator circuit.

In an optional example, the linear regulator circuit comprises a fourth MOS transistor, a fixed resistor, an adjustable resistor and an amplifier, wherein the fourth MOS transistor is triggered to be turned on by a high level; the fixed resistor and the adjustable resistor are connected in series between a pinch-off voltage source and a first electrode of the fourth MOS transistor; a positive phase input end of the amplifier is connected between the fixed resistor and the adjustable resistor, a negative phase input end of the amplifier is connected with a reference voltage source, and an output end of the amplifier is connected with a third electrode of the fourth MOS transistor; and a second electrode of the fourth MOS transistor is connected with a signal source of the source voltage signal.

In an optional example, the clock signal generation sub-circuit comprises a fifth MOS transistor, a sixth MOS transistor, a seventh MOS transistor and an eighth MOS transistor, wherein the fifth MOS transistor and the seventh MOS transistor are triggered to be turned on by a low level, and a first electrode of the fifth MOS transistor and a first electrode of the seventh MOS transistor are connected with a positive voltage source of the voltage conversion circuit; the sixth MOS transistor and the eighth MOS transistor are triggered to be turned on by a high level, and a second electrode of the sixth MOS transistor and a second electrode of the seventh MOS transistor are connected with a signal source of the source voltage signal; a third electrode of the fifth MOS transistor and a third electrode of the sixth MOS transistor are connected with a clock signal input end; a second electrode of the fifth MOS transistor and a first electrode of the sixth MOS transistor are connected with a first output end of the clock signal generation sub-circuit, a third electrode of the seventh MOS transistor and a third electrode of the eighth MOS transistor respectively; and the second electrode of the seventh MOS transistor and a first electrode of the eighth MOS transistor are connected with a second output end of the clock signal generation sub-circuit, wherein the first output end is configured to output the first clock sub-signal, and the second output end is configured to output the second clock sub-signal; or the first output end is configured to output the second clock sub-signal, and the second output end is configured to output the first clock sub-signal.

In an optional example, the charge pump circuit comprises at least one stage circuit unit that comprises a voltage conversion sub-circuit, a reset sub-circuit and a second output circuit, wherein the voltage conversion sub-circuit is connected with a first electrode of a MOS transistor in the second output circuit and is configured to output a converted positive voltage signal to the first electrode of the MOS transistor in the second output circuit under the control of the voltage doubling clock signal; and the reset sub-circuit is connected with a third electrode of the MOS transistor in the second output circuit and an output end of the charge pump circuit, and is configured to output a third clock signal to the third electrode of the MOS transistor in the second output circuit, wherein the MOS transistor in the second output circuit is configured to be turned on when the third clock signal is at a low level, and a voltage of the third clock signal at the low level is greater than a voltage of the source voltage signal.

In an optional example, the reset sub-circuit is configured to output the third clock signal to the third electrode of the MOS transistor in the second output circuit under the driving of the first clock signal; the first clock signal comprises a third clock sub-signal and a fourth clock sub-signal; and the third clock sub-signal and the fourth clock sub-signal are the same in cycle, level states of the third clock sub-signal and the first clock sub-signal at the same instant are the same, and level states of the third clock sub-signal and the fourth clock sub-signal at the same instant are opposite.

In an optional example, voltages of the third clock sub-signal and the fourth clock sub-signal at a high level are the same as a voltage of a positive voltage source of the voltage conversion circuit, and voltages of the third clock sub-signal and the fourth clock sub-signal at a low level are the same as the voltage of the source voltage signal.

In an optional example, the second output circuit comprises a ninth MOS transistor and a tenth MOS transistor, and the reset sub-circuit comprises an eleventh MOS transistor, a twelfth MOS transistor, a first capacitor and a second capacitor, wherein the ninth MOS transistor, the tenth MOS transistor, the eleventh MOS transistor, and the twelfth MOS transistor are triggered to be turned on by a low level; the third clock sub-signal is input by an end of the first capacitor, and the other end of the first capacitor is connected with a third electrode of the ninth MOS transistor, a first electrode of the eleventh MOS transistor and a third electrode of the twelfth MOS transistor; the fourth clock sub-signal is input by an end of the second capacitor, and the other end of the second capacitor is connected with a third electrode of the tenth MOS transistor, a first electrode of the twelfth MOS transistor and a third electrode of the eleventh MOS transistor; a second electrode of the ninth MOS transistor, a second electrode of the tenth MOS transistor, a second electrode of the eleventh MOS transistor and a second electrode of the twelfth MOS transistor are connected with a voltage output end of the stage circuit unit; and the voltage conversion sub-circuit is configured to apply a converted positive voltage signal to a first electrode of the ninth MOS transistor when the third clock sub-signal is at a low level, and to apply the converted positive voltage signal to a first electrode of the tenth MOS transistor when the fourth clock sub-signal is at a low level.

In an optional example, the voltage doubling clock signal comprises a fifth clock sub-signal and a sixth clock sub-signal that are the same in cycle, wherein level states of the fifth clock sub-signal and the first clock sub-signal at the same instant are the same, and level states of the fifth clock sub-signal and the sixth clock sub-signal at the same instant are opposite; the voltage conversion sub-circuit comprises a thirteenth MOS transistor, a fourteenth MOS transistor, a fifteenth MOS transistor, a sixteenth MOS transistor, a third capacitor, a fourth capacitor, a fifth capacitor and a sixth capacitor, wherein the thirteenth MOS transistor, the fourteenth MOS transistor, the fifteenth MOS transistor and the sixteenth MOS transistor are triggered to be turned on by a high level; the fifth clock sub-signal is input by an end of the third capacitor and an end of the fifth capacitor, and the other end of the third capacitor is connected with a third electrode of the thirteenth MOS transistor, a second electrode of the fifteenth MOS transistor and a third electrode of the sixteenth MOS transistor; the sixth clock sub-signal is input by an end of the fourth capacitor and an end of the sixth capacitor, and the other end of the fourth capacitor is connected with a third electrode of the fourteenth MOS transistor, a second electrode of the sixteenth MOS transistor and a third electrode of the fifteenth MOS transistor; a first electrode of the thirteenth MOS transistor, a first electrode of the fourteenth MOS transistor, a first electrode of the fifteenth MOS transistor and a first electrode of the sixteenth MOS transistor are connected with a voltage input end of the stage circuit unit; and the other end of the fifth capacitor is connected with a second electrode of the thirteenth MOS transistor and a first electrode of the ninth MOS transistor; and the other end of the sixth capacitor is connected with a second electrode of the fourteenth MOS transistor and a first electrode of the tenth MOS transistor.

In another aspect, provided is a memory device which comprises a peripheral circuit and a memory cell array, wherein the peripheral circuit comprises one or more voltage generation circuits as described above.

In still another aspect, provided is a memory system which comprises one or more memory devices, and a controller coupled to the memory devices and configured to control the memory devices, wherein the memory device comprises a peripheral circuit and a memory cell array; and the peripheral circuit comprises one or more memory devices as described above.

### BRIEF DESCRIPTION OF THE DRAWINGS

In order to describe the technical solutions in examples of the present disclosure more clearly, the drawings required to be used in the examples will be simply introduced below. It is apparent that the drawings in the following descriptions are only some examples of the present disclosure. Those of ordinary skill in the art may further obtain other drawings according to these drawings without creative work.

FIG. 1 is a schematic diagram of a computer system provided by an example of the present disclosure;

FIG. 2 is a schematic structural diagram of a memory card involved in the present disclosure;

FIG. 3 is a schematic structural diagram of a solid state drive involved in the present disclosure;

FIG. 4 is a block diagram of a memory device shown in an example of the present disclosure;

FIG. 5 is a schematic circuit diagram of a memory device shown in an example of the present disclosure;

FIG. 6 is a side cross-sectional view of a memory string shown in an example of the present disclosure;

FIG. 7 is a schematic diagram of a circuit structure of a clock voltage doubling circuit;

FIG. 8 is a level timing diagram of a clock signal;

FIG. 9 is a schematic structural diagram of a basic stage circuit unit of a charge pump circuit;

FIG. 10 is a structural block diagram of a voltage generation circuit provided by an example of the present disclosure;

FIG. 11 is a structural block diagram of another voltage generation circuit provided by an example of the present disclosure;

FIG. 12 is a structural block diagram of another voltage generation circuit provided by an example of the present disclosure;

FIG. 13 is a schematic diagram of a clock signal involved in the present disclosure;

FIG. 14 is a structural block diagram of a voltage generation circuit provided by an example of the present disclosure;

FIG. 15 is a schematic structural diagram of a low voltage generation sub-circuit provided by examples of the present disclosure; and

FIG. 16 is a structural schematic diagram of another low voltage generation sub-circuit provided by examples of the present disclosure;

FIG. 17 is a schematic structure diagram of a clock signal generation sub-circuit provided by examples of the present disclosure;

FIG. 18 is a schematic structural diagram of a clock voltage doubling circuit involved in the present disclosure;

FIG. 19 is a structural schematic diagram of another voltage generation circuit involved in the present disclosure;

FIG. 20 is a schematic structural diagram of a stage circuit unit involved in the present disclosure;

FIG. 21 is a structural block diagram of a memory device provided by an example of the present disclosure; and

FIG. 22 is a structural block diagram of a memory system provided by an example of the present disclosure.

### DETAILED DESCRIPTION

Implementations of the present disclosure are further described in detail below with reference to the drawings.

A computer system provided by examples of the present disclosure may comprise a host and a memory system. The memory system may comprise a 3D memory device, which, for example, may be a 3D NAND flash.

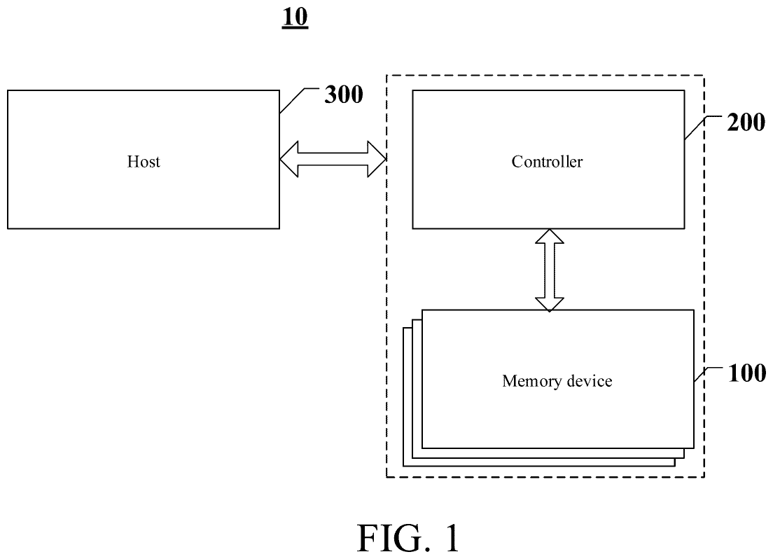

FIG. 1 is a schematic diagram of a computer system provided by an example of the present disclosure. As shown in FIG. 1, the computer system 10 comprises one or more memory devices 100, and a controller 200 coupled to the memory devices 100 and configured to control the memory devices 100. The controller 200 may be also referred to as a memory controller.

The controller 200 may be configured to control operations performed by the memory device 100, for example, read, erase, write, and program operations. The controller 200 may be further configured to manage various functions with respect to data stored or to be stored in the memory device 100, including, but not limited to, bad-block management, garbage collection, logical-to-physical address conversion, wear leveling, etc. In an example, the controller 200 may be further configured to process error correcting codes (ECCs) with respect to the data read from or written to the memory device 100. The controller 200 may further perform any other suitable functions, for example, formatting the memory device 100.

The controller 200 may also communicate with an external device according to a particular communication protocol. In an example, the controller 200 may communicate with the external device through at least one of various interface protocols which may include a Universal Serial Bus (USB) protocol, a Multi-Media Card (MMC) protocol, a Peripheral Component Interconnect (PCI) protocol, a PCI-Express (PCI-E) protocol, an Advanced Technology Attachment (ATA) protocol, a serial-ATA protocol, a parallel-ATA protocol, a Small Computer System Interface (SCSI) protocol, an Enhanced Small Drive Interface (ESDI) protocol, an Integrated Drive Electronics (IDE) protocol and a Fire wire protocol.

In an optional example, the controller 200 and the one or more memory devices 100 may be integrated into various types of electronic devices. The electronic devices may be a mobile phone, a desktop computer, a laptop computer, a tablet computer, a vehicle computer, a gaming console, a printer, a positioning device, a wearable electronic device, a smart sensor, a virtual reality (VR) device, an augmented reality (AR) device, or any other suitable electronic devices having memory devices therein. Under this scenario, as shown in FIG. 1, the computer system 10 further comprises a host 300. The controller 200 is coupled to the host 300. The controller 200 may manage data stored in the memory device 100, and communicate with the host 300, so as to realize functions of the above-mentioned electronic devices.

In some other examples, the controller 200 and the one or more memory devices 100 may be integrated into various types of memory apparatuses.

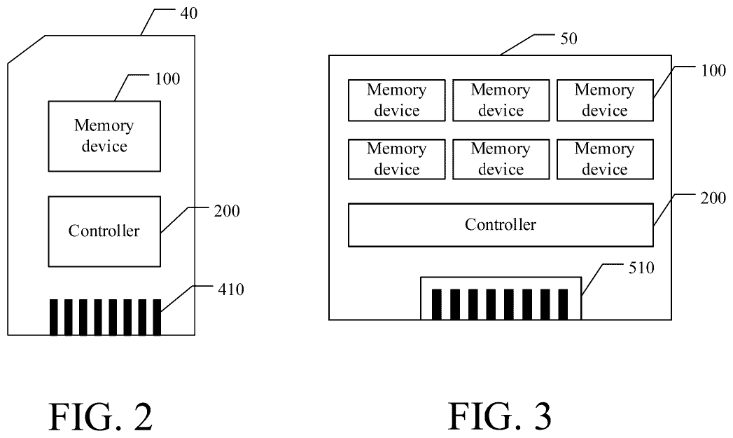

As one example, FIG. 2 is a schematic structural diagram of a memory card involved in the present disclosure. As shown in FIG. 2, the controller 200 and a single memory device 100 may be integrated into a memory card 40. The memory card 40 may comprise a Personal Computer Memory Card International Association (PCMCIA (PC)) card, a Compact Flash (CF) card, a Smart Media (SM) card, a memory stick, a Multi-Media Card (MMC), a reduced-size MMC (RS-MMC), a micro-MMC, a Secure Digital (SD) card, a Universal Flash Storage (UFS), etc. As shown in FIG. 2, the memory card 40 may further comprise a connector 41 coupling the memory card 40 with a host.

As another example, FIG. 3 is a schematic structural diagram of a solid state drive involved in the present disclosure. As shown in FIG. 3, the controller 200 and a plurality of memory devices 100 may be integrated into a solid state drive (SSD) 50. The solid state drive 50 may further comprise a connector 301 coupling the solid state drive 50 with a host. A memory capacity and/or operation speed of the solid state drive 50 are greater than those of the memory card 40.

In addition, the memory device 100 in FIGS. 1 to 3 may be any memory device involved in the examples of the present disclosure, for example, may be a 3D NAND memory device. A structure of the memory device 100 is explained below.

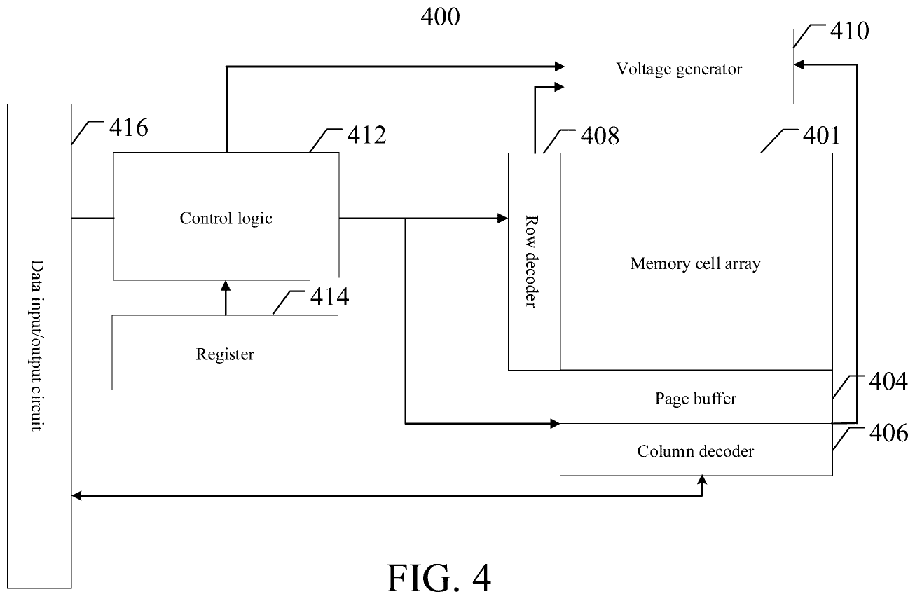

FIG. 4 is a block diagram of a memory device shown in an example of the present disclosure. Referring to FIG. 4, the memory device 400 may comprise a memory cell array 401, a page buffer 404, a column decoder 406, a row decoder 408, a voltage generator 410, a control logic 412, a register 414, and a data input/output circuit 416. It is to be understood that, in some examples, additional peripheral circuits not shown in FIG. 4 may be included as well.

The page buffer 404 may be configured to read and program (write) data from and to the memory cell array 401 according to a control signal from the control logic 412. In one example, the page buffer 404 may store data (write data) to be programmed into a select page of the memory cell array 401. In another example, the page buffer 404 may output read data in a program verification operation to ensure that the data has been properly programmed into a corresponding memory cell coupled to a selected word line of the memory cell array 401. The column decoder 406 may operate in response to the control signal provided by the control logic, so as to select one or more NAND memory strings in the memory cell array 401. The row decoder may operate in response to the control signal provided by the control logic, and select/unselect a selected row of the memory cell array 401. The row decoder may be further configured to supply a voltage generated from the voltage generator 410 to a selected word line and an unselected word line of the memory cell array 401. As described below in detail, the row decoder 408 is configured to perform an erase operation on memory cells coupled to one or more selected word lines in the memory cell array 401. The voltage generator 410 may use an external supply voltage or an internal supply voltage to generate various voltages required by the memory device, such as program voltages, read voltages, pass voltages, verify voltages, bit line voltages, etc., and a combination thereof.

The control logic 412 may be coupled to the voltage generator 410, the page buffer 404, the column decoder 406, the row decoder 408, the data input/output circuit 416, etc., and is configured to control operations of each peripheral circuit. The control logic may generate an operation signal in response to a command or control signal from a memory controller. The register 414 may be coupled to the control logic 412 and comprise a state register, a command register, and an address register, so as to store state information, a command operation code (OP code), and a command address for controlling the operations of each peripheral circuit. The data input/output circuit 416 may be coupled to the control logic 412, and act as a control buffer to buffer and relay a control command received from a host (not shown) to the control logic 412, and to buffer and relay the state information received from the control logic 412 to the host. The data input/output circuit 416 may be also coupled to the column decoder, and act as a data input/output interface and a data buffer to buffer and relay the data to or from the memory cell array 401.

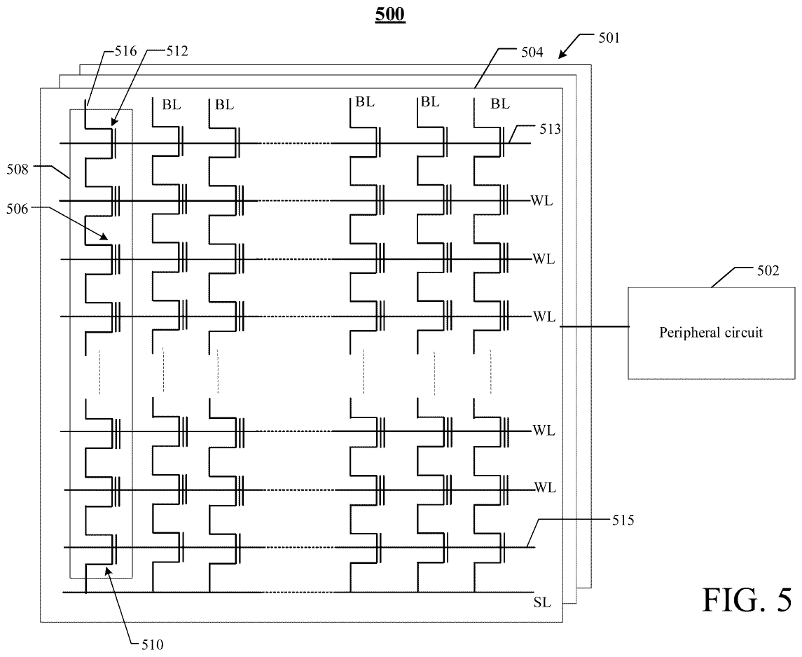

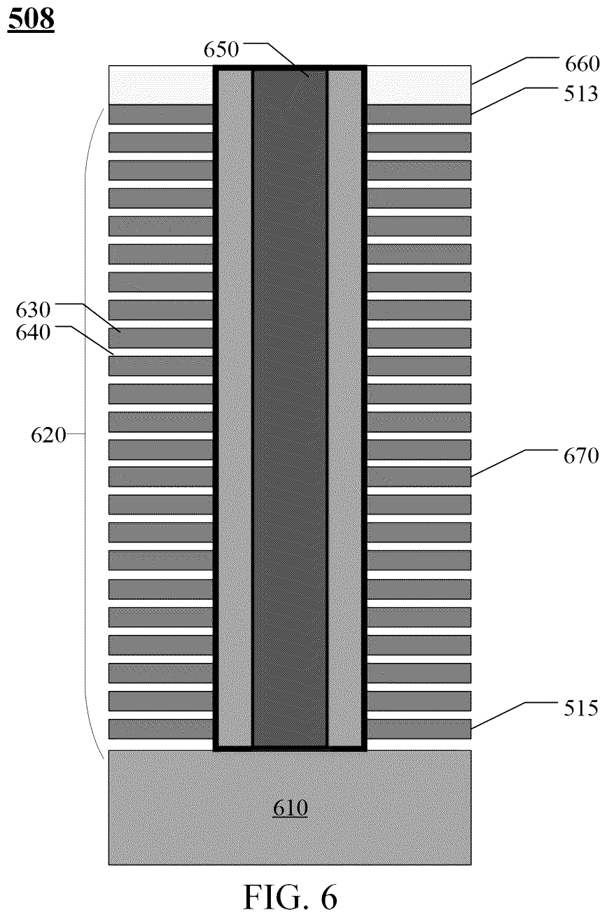

FIG. 5 is a schematic circuit diagram of a memory device shown in an example of the present disclosure. As shown in FIG. 5, a memory device 500 may comprise a memory cell array device 501, and a peripheral circuit 502 coupled to the memory cell array device 501. The memory cell array device 501 may be a NAND flash memory cell array, wherein memory cells 506 are provided in an array of NAND memory strings 508, and each NAND memory string 508 vertically extends above a substrate (not shown). In some implementations, each NAND memory string 508 comprises a plurality of memory cells 506 coupled in series and stacked vertically. Each memory cell 506 may be either a floating gate type memory cell that comprises a floating gate transistor, or a charge trapping type memory cell that comprises a charge trapping transistor. In some implementations, each memory cell 506 is a single-level cell (SLC) that has two possible memory states and may store one bit of data. For example, a first memory state “0” may correspond to a first voltage range, and a second memory state “1” may correspond to a second voltage range. In some implementations, each memory cell 506 is a multi-level cell that can store more than one bit of data in more than two memory states. For example, each cell may store two bits (e.g., multi-level cell (MLC)) per cell, store three bits (e.g., triple-level cell (TLC)) per cell, or store four bits (e.g., quad-level cell (QLC)) per cell.

As shown in FIG. 5, each NAND memory string 508 may comprise at least one source select transistor 510 at its source end, and at least one drain select transistor 512 at its drain end. The source select transistor 510 and the drain select transistor 512 may be configured to activate a selected NAND memory string 508 during read and program operations. In some implementations, sources of the NAND memory strings 508 in the same block 504 are coupled through the same source line (SL). According to some implementations, the drain select transistor 512 of each NAND memory string 508 is coupled to a respective bit line 516. In some implementations, each NAND memory string 508 is configured to be selected or unselected by applying a select voltage or an unselect voltage (e.g., 0 V) to the respective drain select transistor 512 via one or more drain select lines 513 and/or by applying a select voltage or an unselect voltage (e.g., 0 V) to the respective source select transistor 510 via one or more source select lines 515.

As shown in FIG. 5, a memory cell array may comprise a plurality of blocks. In some implementations, each block 504 is a basic data unit for an erase operation, e.g., all of the memory cells 506 on the same block 504 are erased at the same time.

FIG. 6 is a side cross-sectional view of a memory string shown in an example of the present disclosure. Referring to FIG. 6, the memory string 508 may vertically extend through a memory cell stack layer 620 above a doped semiconductor layer 610. The doped semiconductor layer 610 is coupled to a source line. In some implementations, the doped semiconductor layer 610 is a N-type doped semiconductor layer, and in this case, the doped semiconductor layer 610 may be used as a substrate, e.g., a N-type substrate. In some other implementations, the doped semiconductor layer 610 is a P-type doped semiconductor layer, and in this case, the doped semiconductor layer 610 is a P well in the substrate, and the substrate in this case is a P-type substrate.

The memory cell stack layer 620 comprises alternate gate conductive layers 630 and gate-to-gate dielectric layers 640. The number of pairs of the gate conductive layers 630 and the gate-to-gate dielectric layers 640 in the memory cell stack layer 620 may determine the number of memory cells in a memory array. The gate conductive layer 630 may comprise a conductive material that includes, but is not limited to, tungsten (W), cobalt (Co), copper (Cu), aluminum (Al), polysilicon, doped silicon, silicides, or any combination thereof. In a possible implementation, each gate conductive layer 630 comprises a metal layer, e.g., a tungsten layer. In some implementations, each gate conductive layer 630 comprises a doped polysilicon layer. Each gate conductive layer 630 may comprise a gate surrounding the memory cell, and may horizontally extend at the top of the memory cell stack layer 620 as a drain select line (DSL) 513, horizontally extend at the bottom of the memory cell stack layer 620 as a source select line (SSL) 515, or horizontally extend between the DSL and the SSL as a word line (WL) 670.

As shown in FIG. 6, the memory string 508 further comprises a channel structure 650 vertically extending through the memory cell stack layer 620. The channel structure 650 comprises channel holes filled with at least one semiconductor material (e.g., a semiconductor channel) and at least one dielectric material (e.g., a memory film). In some implementations, the semiconductor channel comprises silicon (e.g., the memory film). In some implementations, the memory film is a composite dielectric layer comprising a tunnel layer, a trap layer, and a blocking layer. The channel structure 650 may have a cylindrical shape (e.g., a pillar shape). According to some implementations, the semiconductor channel, the trap layer (also referred to as a memory layer), and the blocking layer are arranged radially from a center toward an outer surface of a pillar in this order. The tunnel layer may comprise silicon oxide, silicon oxynitride, or any combination thereof. The trap layer may comprise silicon nitride, silicon oxynitride, or any combination thereof. The blocking layer may comprise silicon oxide, silicon oxynitride, a high dielectric constant (high-k) dielectric, or any combination thereof. In one example, the memory film may comprise a composite layer of silicon oxide/silicon oxynitride/silicon oxide.

As shown in FIG. 6, a doped semiconductor layer 660 is stacked on the top of the memory cell stack layer 620 in the memory string 508, is also referred to as a bit line contact, is coupled to a bit line for connection, and is a N-type doped semiconductor layer.

In the event that the doped semiconductor layer 660 is the N-type doped semiconductor layer, an erase operation may be performed on the memory string 508 in a gate-induced drain leakage (GIDL) erase manner through the bit line to which the doped semiconductor layer 660 is coupled and the DSL to which a TSG in the memory string 508 is coupled. For example, an erase voltage is applied to the bit line to which the doped semiconductor layer 660 is coupled such that the erase voltage acts on the doped semiconductor layer 660, and a voltage less than the erase voltage is applied to the DSL to which the TSG in the memory string 508 is coupled such that a voltage difference is formed between a gate of the TSG and the doped semiconductor layer 660. The voltage difference causes band-to-band tunneling to occur at a position between the gate of the TSG and the doped semiconductor layer 660 and generates GIDL, and holes in the GIDL moves from that position to a channel of the memory string 508, such that hole injection from the position to the channel of the memory string 508 is realized, thereby raising the potential of the channel. A voltage (referred to as a low voltage, such as 0 V) less than the erase voltage is applied to a word line to which each memory cell in the memory string 508 is coupled, such that the low voltage acts on the gate of the memory cell. As the potential of the channel of the memory cell increases, and when the voltage difference between the gate of the memory cell and the channel of the memory cell increases, and is greater than a tunneling voltage of the memory cell, a tunneling effect is generated between the channel of the memory cell and the gate of the memory cell due to the voltage difference, such that the holes in the channel of the memory cell are tunneled to the memory layer of the memory cell to eliminate electrons in the memory layer, thereby realizing the erasing of the memory cell.

In some examples, in the event that the doped semiconductor layer 610 is the N-type doped semiconductor layer, the erase operation may be performed on a substring block in a GIDL erase manner through the source line to which the doped semiconductor layer 610 is coupled and an SSL to which a BSG in the memory string 508 is coupled. For example, the erase voltage is applied to the source line, and a voltage (referred to as a low voltage) less than the erase voltage is applied to the SSL to which the BSG is coupled to generate the GIDL at a position between a gate of the BSG and the doped semiconductor layer 610, and the holes in the GIDL move toward the channel, such that hole injection from the position to the channel of the memory string 508 is realized, thereby raising the potential of the channel. A low voltage is applied to the word line to which each memory cell in the memory string 508 is coupled; as the potential of the channel of the memory cell increases, and when the voltage difference between the gate of the memory cell and the channel of the memory cell is greater than the tunneling voltage of the memory cell, the holes in the channel are tunneled to the memory layer of the memory cell to eliminate the electrons in the memory layer, thereby realizing the erasing of the memory cell.

Based on this, when both the doped semiconductor layer 610 and the doped semiconductor layer 610 are the N-type doped semiconductor layers, a peripheral circuit may perform the erase operation on the memory string 508 at any end thereof in the GIDL erase manner (e.g., a single-end GIDL erase manner), or may perform the erase operation on the memory string 508 at both ends thereof respectively in the GIDL erase manner (e.g., a double-end GIDL erase manner).

In some other examples, in the event that the doped semiconductor layer 610 is the P-type doped semiconductor layer, the erase operation is performed on the memory string 508 based on an erase manner of the P-type doped semiconductor layer. For example, the erase voltage is applied to the source line such that the erase voltage acts on the P-type doped semiconductor layer, and the erase voltage causes the P-type doped semiconductor layer to generate holes. A low voltage is applied to the BSG of the memory string 508 and the word line to which each memory cell is coupled, such that the low voltage acts on the gate of the BSG and the gate of each memory cell. Since the low voltage is less than the erase voltage, the holes move from the P-type doped semiconductor layer to the channel of the memory string 508 to realize hole injection from the P-type doped semiconductor layer to the channel, thereby raising the potential of the channel. As the potential of the channel of the memory cell increases, and when the voltage difference between the gate of the memory cell and the channel of the memory cell is greater than the tunneling voltage of the memory cell, the holes in the channel are tunneled to the memory layer of the memory cell to eliminate the electrons in the memory layer, thereby realizing the erasing of the memory cell.

Based on this, in the event the doped semiconductor layer 660 is the N-type doped semiconductor layer and the doped semiconductor layer 610 is the P-type doped semiconductor layer, double-end erase may be performed on the memory string 508. For example, single-end GIDL erase is performed at an end of the memory string 508 close to the N-type doped semiconductor layer, and erasing based on the P-type doped semiconductor layer is performed at the other end of the memory string 508. Alternatively, single-end erase is performed on the memory string 508. For example, single-end GIDL erase is performed at an end of the memory string 508 close to the P-type doped semiconductor layer, and erasing based on the P-type doped semiconductor layer is not performed at the other end of the memory string 508. Alternatively, single-end GIDL erase is not performed at an end of the memory string 508 close to the P-type doped semiconductor layer, and erasing based on the P-type doped semiconductor layer is performed at the other end of the memory string 508.

Technical details undisclosed in the memory-related hardware examples are understood with reference to the descriptions about the computer system examples and method examples of the present disclosure.

A charge pump circuit in a 3D NAND generates different voltage sources for the read, write and erase operations. A multi-stage series charge pump circuit will increase the voltage by alternate toggle of a clock. When an output voltage is constant, the increase in the number of series stages will lead to a reduction in the efficiency of a charge pump. Therefore, in order to improve the efficiency of the charge pump, the number of stages of the series charge pump should be reduced as much as possible in the event of satisfying the driving capability and a target output voltage. In some implementations, a clock voltage doubling circuit is configured to increase a clock swing.

In some implementations, a positive charge pump uses the clock voltage doubling circuit to reduce the number of stages of the series charge pump, thereby improving the efficiency and the driving force of the charge pump. In an example, different voltages generated by the charge pump circuit in the 3D NAND may be configured to perform read, write and erase operations on a memory array. The multi-stage series charge pump circuit may increase the voltage by alternate toggle of a clock signal. When an output voltage is constant, the increase in the number of series stages will lead to a reduction in the efficiency of a charge pump. Therefore, in order to improve the efficiency of the charge pump, the number of stages of the series charge pump should be reduced as much as possible in the event of satisfying the driving capability and the target output voltage. In some implementations, the clock voltage doubling circuit is configured to increase a voltage swing (e.g., a voltage difference between a high level and a low level of a voltage doubling clock signal) of the clock signal of an input charge pump circuit.

Due to the limitations of processes, both a PMOS transistor in the clock voltage doubling circuit which outputs the voltage doubling clock signal and a PMOS transistor in the charge pump have the problem of a safe operating area (SOA). That is to say, the voltage withstanding PMOS transistors in the clock voltage doubling circuit and the clock voltage doubling circuit need to withstand a positive voltage signal with a high voltage value (e.g., twice a voltage value of a positive voltage source) during operation, such that a suitable voltage (e.g., less than a Vcc voltage) needs to be generated additionally based on a supply voltage (e.g., denoted by Vcc) as a positive voltage source (e.g., denoted by Vsup) of the clock voltage doubling circuit to solve the problem of the SOA. However, this will limit the voltage swing of the voltage doubling clock signal output by the clock voltage doubling circuit, thereby limiting the driving capability and efficiency of the charge pump.

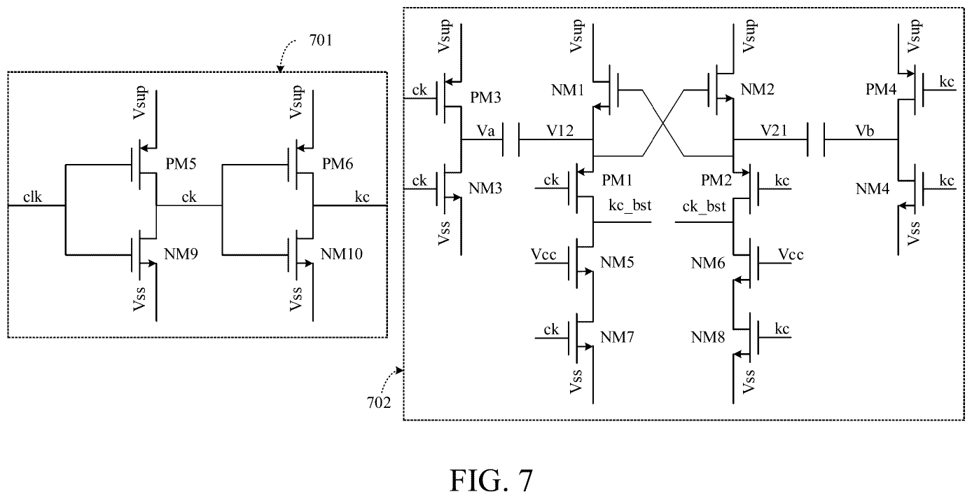

Referring to FIG. 7, FIG. 7 illustrates a circuit structure diagram of a clock voltage doubling circuit. As shown in FIG. 7, clk is a clock signal at a certain frequency, Vsup is a voltage signal of a positive voltage source and may be generated from Vcc through a low drop-out regulator (LDO) circuit (Vsup≤Vcc). Ideally, Vsup may be Vcc if no voltage withstanding problem exists. Vss is a voltage source of a source voltage signal (also referred to as a negative voltage source in some scenarios). Voltage swings of the output voltage doubling clock signals ck_bst and kc_bst may be increased from voltage swings (Vsup) of ck and kc to 2*Vsup through the clock voltage doubling circuit shown in FIG. 7.

As shown in FIG. 7, the clock voltage doubling circuit comprises 6 PMOS transistors (corresponding to PM1˜PM6 in FIG. 7) and 10 N-type MOS transistors (NMOS transistors, corresponding to NM1-NM10 in FIG. 7).

PM5 and NM9 generate clock signals ck under the control of the clock signal clk; PM6 and NM10 generates clock signals kc under the control of the clock signal ck; and the clock signals ck and kc trigger to generate the clock signals ck_bst and kc_bst. In an example, in the circuit structure shown in FIG. 7, a position in a left circuit portion 701 marked with “ck” is a port outputting the clock signal ck; a position in a right circuit portion 702 marked with “ck” is a port inputting the clock signal ck, and the position in the left circuit portion 701 marked with “ck” is connected with the position in the right circuit portion 702 marked with “ck”. Correspondingly, a position in the left circuit portion 701 marked with “kc” is a port outputting the clock signal kc; a position in the right circuit portion 702 marked with “kc” is a port inputting the clock signal kc, and the position in the left circuit portion 701 marked with “kc” is connected with the position in the right circuit portion 702 marked with “kc”. Furthermore, in FIG. 7, a position marked with “ck_bst” is a port outputting the clock signal ck_bst, a position marked with “kc_bst” is a port outputting the clock signal kc_bst, and positions marked with “clk”, “Vsup”, “Vss” and “Vcc” are ports inputting the clock signal clk, the voltage signal Vsup of the positive voltage source, the source voltage signal Vss and the supply voltage signal Vcc respectively.

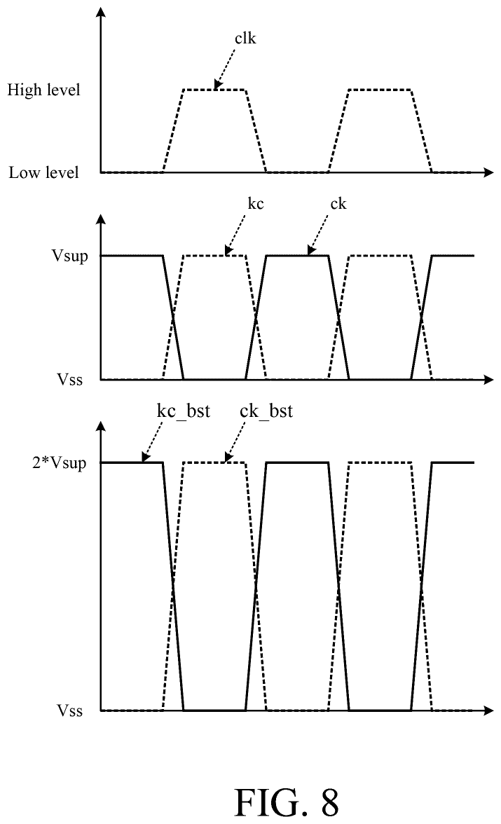

Referring to FIG. 8, FIG. 8 illustrates a level timing diagram of a clock signal involved in the present disclosure. FIG. 8 illustrates level states and voltage values of the clock signals clk, ck, kc, ck_bst and kc_bst at various instants.

In conjunction with the left half of FIG. 7 and FIG. 8, when the clk is at a low level, PM5 is triggered to be turned on and output a high level (a voltage value being Vsup) of the clock signal ck, and NM9 is turned off. Meanwhile, the clock signal ck of the high level triggers to turn on NM10 and output a low level (a voltage value being Vss) of the clock signal kc, and PM6 is turned off. Correspondingly, when the clk is at a high level, NM9 is triggered to be turned on and output a low level (a voltage value being Vss) of the clock signal ck, and PM6 is turned off. Meanwhile, the clock signal ck of the low level triggers to turn on PM6 and output a high level (a voltage value being Vsup) of the clock signal kc.

The above-mentioned clock signals ck and kc may control the MOS transistor in the circuit in the right half of FIG. 7 to toggle between an on state and an off state, so as to output the clock signals kc_bst and ck_bst from PM1 and PM2.

In conjunction with the right half of FIG. 7 and FIG. 8, Vcc is maintained at a high level, and when the clock signal ck is at a low level, the clock signal kc is at a high level. At this point, PM1, PM3, NM4, NM5, NM6 and NM8 are turned on, and PM2, PM4, NM3 and NM7 are turned off, a voltage Va becomes Vsup from Vss, and a voltage V12 becomes twice Vsup from Vsup. At this point, since PM1 is in an on state, the voltage V12 is passed to a drain of PM1, and is output as a voltage of a high level of the clock signal ck_bst. Correspondingly, since PM2 is in an off state, the voltage Vss input by NM8 is passed to a drain of PM2 and is output as a voltage of a low level of the clock signal kc_bst.

Similarly, when the clock signal ck is at a high level, the clock signal kc is at a low level. At this point, PM2, PM4, NM3, NM5, NM6 and NM7 are turned on, and PM1, PM3, NM4 and NM8 are turned off, a voltage Vb becomes Vsup from Vss, and a voltage V21 becomes twice Vsup from Vsup. At this point, since PM2 is in an on state, the voltage V21 is passed to the drain of PM2, and is output as a voltage of a high level of the clock signal kc_bst. Correspondingly, since PM1 is in an off state, the voltage Vss input by NM7 is passed to the drain of PM1 and is output as a voltage of a low level of the clock signal ck_bst.

The clock voltage doubling circuit usually uses a 3.3 V device in order to reduce the circuit area. Therefore, in order to avoid the voltage withstanding problem (VGS) when PM1 and PM2 transistors are turned on, a voltage value of Vsup is usually limited, which will affect a voltage value of a high level of the clock signals ck_bst and kc_bst as well, that is to say, the problem of the voltage withstanding SOA problem of PM1 and PM2 will limit amplitudes of ck_bst and kc_bst, thereby affecting the driving capability and efficiency of the charge pump.

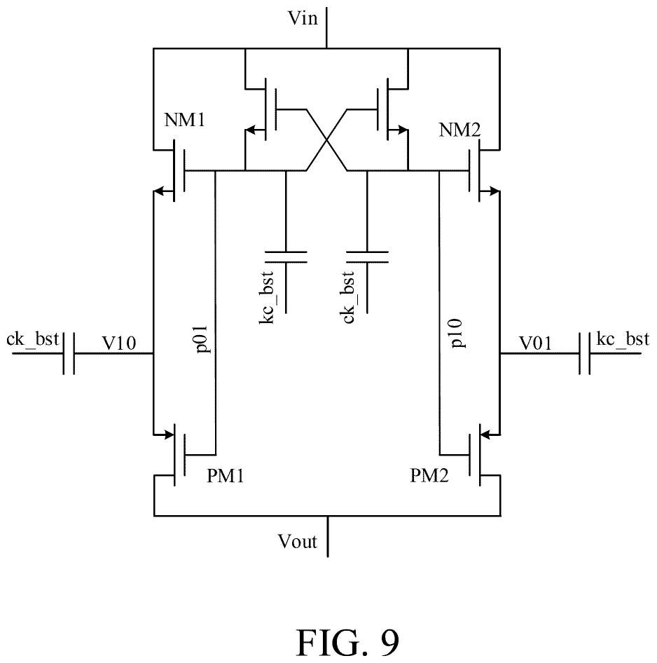

The charge pump circuit (also referred to as a charge pump stage circuit) uses voltage-doubled clock signals ck_bst and kc_bst as input clock signals. Referring to FIG. 9, FIG. 9 illustrates a schematic structural diagram of a basic stage circuit unit of a charge pump circuit involved in the present disclosure.

The basic stage circuit unit shown in FIG. 9 is referred to as a charge pump whose structure is called as a pelliconi structure. In conjunction with FIGS. 8 and 9, the voltage Vss is set as 0, when a level of the clock signal ck_bst becomes a high level from a low level (a voltage value being Vss), V10 becomes Vin+Vck_bst (where Vck_bst is a voltage value of a high level of the clock signal ck_bst) from Vin of a last state. At this point, a potential p01 is pulled down to Vin from V10, and the output PMOS transistor PM1 is turned on to transfer the voltage V10 to Vout. Similarly, when ck_bst is at a low level, kc_bst is at a high level, and PM2 is turned on to transfer the voltage V01 to Vout.

The charge pump circuit consists of one or more groups of basic stage circuit units. The basic stage circuit units of the same group are connected in series, and multiple groups of basic stage circuit units may be connected in parallel.

The structure of the charge pump shown in FIG. 9 also has the voltage withstanding problem when the PMOS transistor is turned on. In an example, due to the process limitations, the PMOS transistor in the stage circuit also uses a 3.3 V device. When amplitudes of ck_bst and kc_bst are large, the voltage withstanding problem will occur when the PMOS transistors PM1 and PM2 are turned on. In conjunction with the structure shown in FIG. 8, since the voltage Vsup is limited in the clock voltage doubling circuit, the swings of output clock signals ck_bst and kc_bst are limited, which can avoid the voltage withstanding problem of the two PMOS transistors but also leads to the reduction in the efficiency of the charge pump.

For one or more of the above-mentioned problems, examples of the present disclosure provide a clock voltage doubling circuit and a charge pump circuit which can improve the efficiency of the charge pump on the basis of improving the voltage withstanding problem of the PMOS transistor.

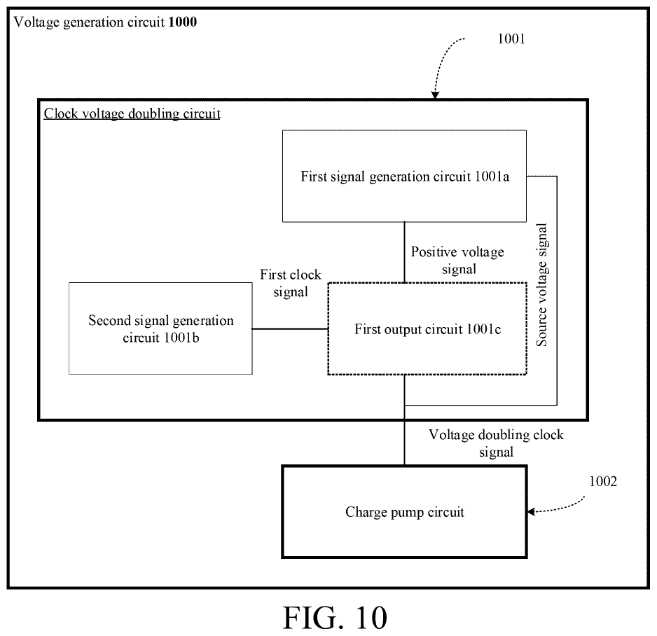

FIG. 10 is a structural block diagram of a voltage generation circuit provided by an example of the present disclosure. As shown in FIG. 10, the voltage generation circuit 1000 comprises a clock voltage doubling circuit 1001 and a charge pump circuit 1002, wherein the clock voltage doubling circuit comprises a first signal generation circuit 1001a, a second signal generation circuit 1001b and a first output circuit 1001c.

The first signal generation circuit 1001a is connected with a first electrode and a second electrode of a MOS transistor in the first output circuit 1001c, the second signal generation circuit 1001b is connected with a third electrode of the MOS transistor in the first output circuit 1001c, and the second electrode of the MOS transistor in the first output circuit 1001c is connected with the charge pump circuit 1002.

The first signal generation circuit 1001a is configured to apply a positive voltage signal to the first electrode of the MOS transistor in the first output circuit 1001c and apply a source voltage signal to the second electrode of the MOS transistor in the first output circuit 1001c under the control of an input first clock signal.

A voltage value of the positive voltage signal is positive, and a numerical value of the positive voltage signal is higher than a numerical value of a voltage of the source voltage signal, for example, the positive voltage signal may be a signal with a voltage value of 1.5 V or higher, and the above-mentioned source voltage signal may be a signal with a voltage value of 0.

The MOS transistor in above-mentioned first output circuit 1001c may be a PMOS transistor or other types of MOS transistors.

The second signal generation circuit 1001b is configured to apply a second clock signal different from the first clock signal to the third electrode of the MOS transistor in the first output circuit 1001c under the control of the input first clock signal.

The first output circuit 1001c is configured to output a voltage doubling clock signal to the charge pump circuit 1002 under the control of the second clock signal.

In a possible implementation, the first electrode, the second electrode and the third electrode of the MOS transistor in the above-mentioned first output circuit 1001c may be a source, a drain and a gate of the MOS transistor respectively, wherein the source and the drain are an input end and an output end of the MOS transistor respectively, the gate is a control end of the MOS transistor, and a pathway between the source and the drain of the MOS transistor may be opened or closed under the control of an input signal of the gate. In the event that the input signal of the gate is a clock signal, the MOS transistor in the first output circuit 1001c will be also turned on or off in a form of a clock circle, that is to say, the MOS transistor in the first output circuit 1001c will also output the clock signal (e.g., the above-mentioned voltage doubling clock signal).

In another possible implementation, the first electrode, the second electrode and the third electrode of the MOS transistor in the above-mentioned first output circuit 1001c may be also the drain, the source and the gate of the MOS transistor.

For the clock voltage doubling circuit using the MOS transistor as an output circuit, an upper limit of a voltage value of the positive voltage signal which the MOS transistor of the output circuit can withstand depends on a voltage value of a control signal of the MOS transistor of the output circuit. In the solution as shown in the above examples of the present disclosure, while one clock signal (the first clock signal) is configured to control to generate a voltage-doubled positive voltage signal, the clock signal is also employed to generate another different control signal (the second clock signal) to control the MOS transistor of the output circuit to output the voltage doubling clock signal to the charge pump circuit, that is to say, the control signal of the MOS transistor of the above-mentioned output circuit is generated by an independent circuit. Therefore, the upper limit of the voltage value of the positive voltage signal which the MOS transistor of the output circuit can withstand may be increased by appropriately setting the voltage value of the control signal of the MOS transistor of the output circuit, thereby increasing a voltage value of a high level of the clock voltage doubling circuit output by the clock voltage doubling circuit. In an example, taking the MOS transistor of the output circuit being a P-type MOS transistor (PMOS) as an example, when the second clock signal applied to the gate (the third electrode) of the PMOS is at a low level, the PMOS transistor is turned on, and the positive voltage signal applied to the source (the first electrode) of the PMOS transistor is output from the drain (the second electrode) of the PMOS transistor as a high level signal of the voltage doubling clock signal. In an on state, a voltage difference between the gate and the source of the PMOS transistor cannot exceed some threshold (denoted as VGS usually), that is to say, in a circuit design, a difference between the voltage value of the above-mentioned positive voltage signal and a voltage value of a low level of the second clock signal needs to be less than VGS. With the solution as shown in the present disclosure, during a design process, the voltage value of the low level of the second clock signal may be increased appropriately in the event of ensuring that the low level of the second clock signal can trigger the PMOS transistor to be turned on, such that the upper limit of the voltage value of the positive voltage signal can be also increased, thereby allowing the PMOS transistor to withstand a positive voltage signal with a higher voltage value, increasing the voltage value of the high level signal of the voltage doubling clock signal output by the PMOS transistor and improving the driving capability and running efficiency of the charge pump circuit subsequently.

In the examples of the present disclosure, when the voltage generation circuit 1000 shown in FIG. 10 above is applied in a memory product such as a NAND, etc., the voltage generation circuit 1000 may achieve a part of the voltage generator 410 of the memory device shown in FIG. 4.

Based on the examples shown in FIG. 10, in a possible implementation, the high level voltage of the voltage doubling clock signal is the same as the voltage of the positive voltage signal, and the low level voltage of the voltage doubling clock signal is the same as the voltage of the source voltage signal.

In the solution shown in the examples of the present disclosure, the input signal of the above-mentioned first signal generation circuit 1001a may comprise a first clock signal, an initial voltage signal and a source voltage signal. The first signal generation circuit 1001a doubles a voltage value of the initial positive voltage signal to obtain the above-mentioned positive voltage signal, and the first signal generation circuit 1001a also applies the above-mentioned positive voltage signal and the source voltage signal to the MOS transistor in the first output circuit 1001c under the control of the first clock signal. Meanwhile, under the control of the second clock signal, the MOS transistor in the first output circuit 1001c alternately outputs the positive voltage signal and the source voltage signal according to clock cycle corresponding to the second clock signal, and the above-mentioned positive voltage signal and source voltage signal that are alternately output are the above-mentioned voltage doubling clock signal.

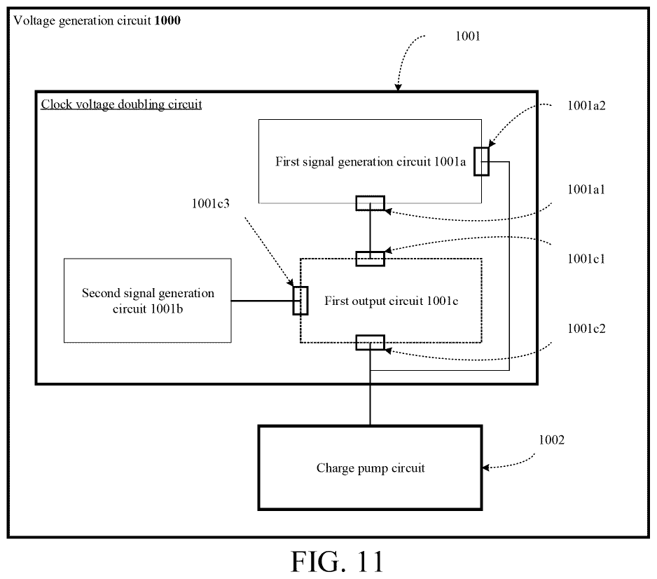

Based on the voltage generation circuit shown in the above-mentioned FIG. 10, referring to FIG. 11, FIG. 11 illustrates a structural block diagram of another voltage generation circuit provided by an example of the present disclosure. As shown in FIG. 11, a first port 1001a1 of the first signal generation circuit 1001a is connected with a first electrode 1001c1 of the MOS transistor in the first output circuit 1001c, and a second port of the first signal generation circuit 1001a is connected with a second electrode 1001c2 of the MOS transistor in the first output circuit 1001c. The MOS transistor in the first output circuit 1001c is configured to output a high level voltage of the voltage doubling clock signal through the second electrode 1001c2 of the MOS transistor in the first output circuit 1001c when the second clock signal applied to a third electrode 1001c3 of the MOS transistor in the first output circuit 1001c is at a low level, and the MOS transistor in the first output circuit 1001c is configured to output a low level voltage of the voltage doubling clock signal through the second electrode 1001c2 of the MOS transistor in the first output circuit 1001c when the second clock signal applied to the third electrode 1001c3 of the MOS transistor in the first output circuit 1001c is at a high level, wherein the voltage of the second clock signal at the low level is greater than the voltage of the source voltage signal.

In the solution shown in the examples of the present disclosure, the first signal generation circuit 1001a applies the positive voltage signal and the source voltage signal to different electrodes of the MOS transistor in the first output circuit 1001c through different ports. Meanwhile, the second signal generation circuit applies the second clock signal to the third electrode of the MOS transistor in the first output circuit 1001c to control the MOS transistor in the first output circuit 1001c to output the voltage doubling clock signal. During this process, when the second clock signal is at a low level, the MOS transistor in the first output circuit 1001c is triggered to be turned on. At this point, in order to avoid the voltage withstanding problem of the MOS transistor in the first output circuit 1001c, a difference between the voltage value of the positive voltage signal applied to the first electrode of the MOS transistor in the first output circuit 1001c and the voltage value of the low level voltage applied to the third electrode of the MOS transistor in the first output circuit 1001c needs to be limited to be below some threshold. On this basis, the examples of the present disclosure set the voltage of the second clock signal at the low level to be greater than the voltage of the source voltage signal and ensure that the MOS transistor in the first output circuit 1001c can be turned on when the second clock signal is at the low level. The voltage of the second clock signal at the low level is increased appropriately, and accordingly, the voltage value of the positive voltage signal may be also increased appropriately in the event of avoiding the voltage withstanding problem of the MOS transistor in the first output circuit 1001c.

For example, compared with the circuit structure shown in FIG. 7 in which, assuming that voltage withstanding upper limits of PM1/PM2 in FIG. 7 and the MOS transistor in the first output circuit 1001c are all 3.3 V, that is to say, a difference between the voltage value of the positive voltage signal applied to the PM1/PM2/first electrode of the MOS transistor in the first output circuit 1001c and the voltage value of the low level voltage applied to PM1/PM2/third electrode of the MOS transistor in the first output circuit 1001c needs to be limited to be below 3.3 V, the low level voltage of the clock signal applied to a gate of the PM1/PM2 is the voltage value (0 V) of the source voltage signal, and it needs to be ensured that the voltage value of 2*Vsup does not exceed 3.3 V at most in order to avoid the voltage withstanding problem in this case, in the circuit structure shown in FIG. 10 or 11, in the event of ensuring that the MOS transistor in the first output circuit 1001c can be triggered to be turned on, the voltage of the second clock signal at the low level may be higher than 0 V appropriately (for example, may be set as 0.2 V), and accordingly, the voltage value of the positive voltage signal applied to the first electrode of the MOS transistor in the first output circuit 1001c does not exceed 3.5 V at most. Compared with the upper limit of the voltage value of 2*Vsup in FIG. 7, the upper limit of the voltage value of the positive voltage signal can be also increased appropriately in the circuit structure shown in FIG. 10 or 11.

In the examples of the present disclosure, for the MOS transistor triggered to be turned on by a low level, the voltage of the low level of the second clock signal applied to the third electrode of the MOS transistor may be increased appropriately, such that the voltage value of the positive voltage signal applied to the MOS transistor may be also increased appropriately in the event of avoiding the voltage withstanding problem of the MOS transistor. Therefore, the voltage value of the high level of the voltage doubling clock signal output by the clock voltage doubling circuit may be increased, which in turn improves the driving capability and running efficiency of the charge pump circuit subsequently.

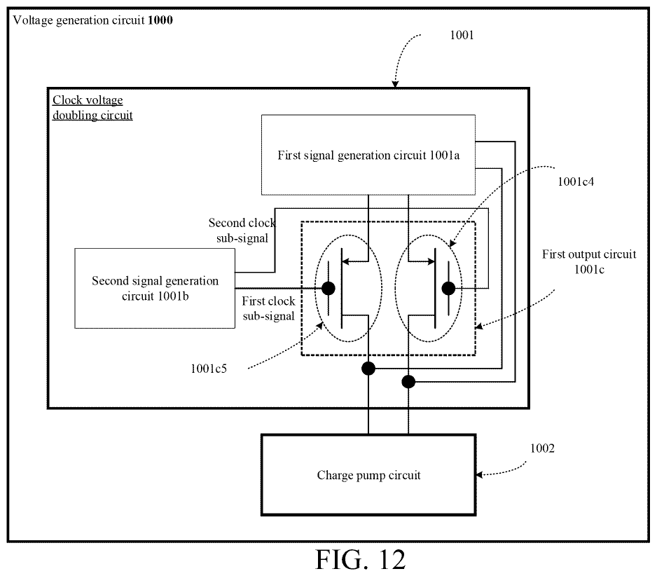

Based on the solution shown in FIG. 10 or 11 above, referring to FIG. 12, FIG. 12 illustrates a structural block diagram of another voltage generation circuit provided by an example of the present disclosure. As shown in FIG. 12, the first output circuit 1001c comprises a first MOS transistor 1001c4 and a second MOS transistor 1001c5.

In the examples of the present disclosure, the first output circuit 1001c comprises two MOS transistors, and the first signal generation circuit 1001a may be connected with first electrodes of the two MOS transistor in the first output circuit 1001c respectively. For example, the first port 1001a1 in the first signal generation circuit 1001a may comprise two sub-ports that are connected with the first electrodes of the two MOS transistors in a one-to-one corresponding manner, such that the positive voltage signal is applied to the first electrodes of the two MOS transistors respectively. Correspondingly, the first signal generation circuit 1001a may be connected with second electrodes of the two MOS transistors in the first output circuit 1001c. For example, the second ports 1001a2 in the first signal generation circuit 1001a may comprise two sub-ports that are connected with the second electrodes of the two MOS transistors in a one-to-one corresponding manner, such that the source voltage signal is applied to the second electrodes of the two MOS transistors respectively.

The second clock signal comprises a first clock sub-signal and a second clock sub-signal. The second signal generation circuit 1001b is configured to apply the first clock sub-signal to a third electrode of the first MOS transistor 1001c4, and apply the second clock sub-signal to a third electrode of the second MOS transistor 1001c5, wherein the first clock sub-signal and the second clock sub-signal are the same in cycle, and level states of the first clock sub-signal and the second clock sub-signal at the same instant are opposite.

In the examples of the present disclosure, the two MOS transistors included in the first output circuit 1001c may output the voltage doubling clock signals respectively, and the voltage doubling clock signals output by the two MOS transistors respectively are two clock signals with opposite clock cycles (or complementary clock cycles).

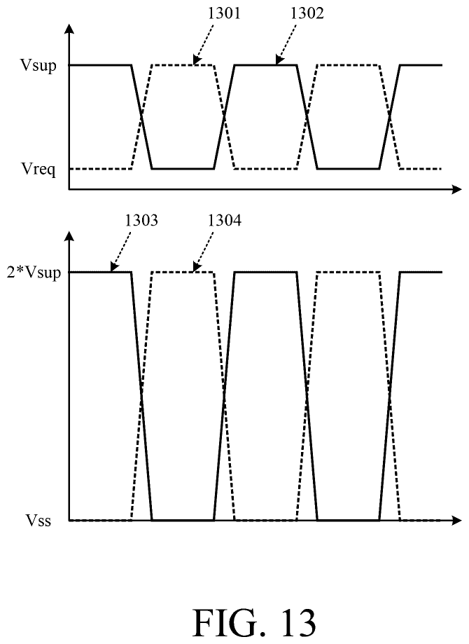

Referring to FIG. 13, FIG. 13 illustrates a schematic diagram of a clock signal involved in the present disclosure. In conjunction with FIGS. 12 and 13, the first clock sub-signal 1301 is applied to the third electrode of the first MOS transistor 1001c4, the second clock sub-signal 1302 is applied to the third electrode of the second MOS transistor 1001c5, and the level states of the first clock sub-signal 1301 and the second clock sub-signal 1302 at the same instant are opposite. Correspondingly, level states of the voltage doubling clock signals output by the first MOS transistor 1001c4 and the second MOS transistor 1001c5 respectively at the same instant are also opposite. For example, when the first clock sub-signal 1301 is at a low level (Vreq), the second clock sub-signal 1302 is at a high level (Vsup). At this point, the first MOS transistor 1001c4 is turned on, the output voltage doubling clock signal 1303 is at a high level (2*Vsup), the second MOS transistor 1001c5 is turned off, and the output voltage doubling clock signal 1304 is at a low level (Vss). On the contrary, when the first clock sub-signal 1301 is at a high level, the second clock sub-signal 1302 is at a low level. At this point, the first MOS transistor 1001c4 is turned off, the output voltage doubling clock signal 1303 is at a low level, the second MOS transistor 1001c5 is turned on, and the output voltage doubling clock signal 1304 is at a high level.

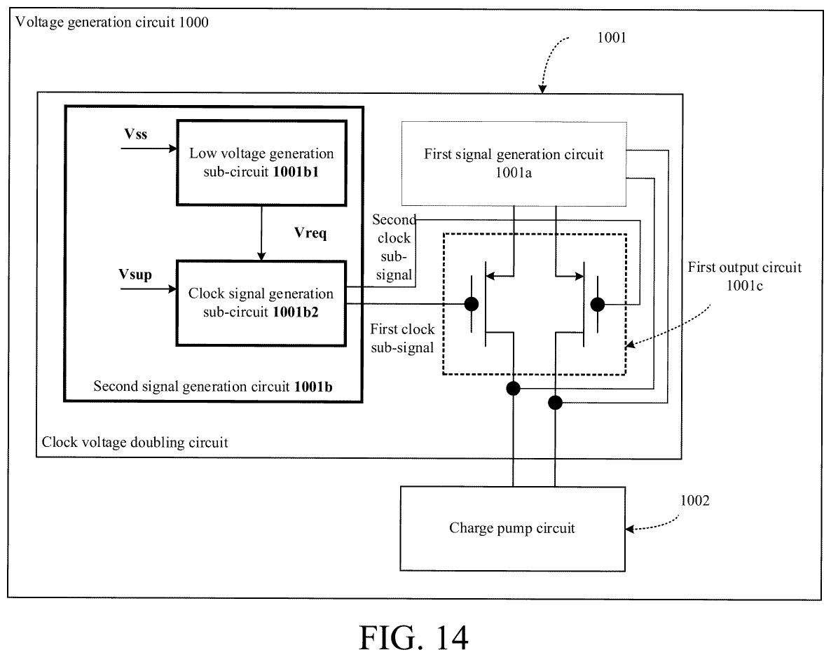

Based on the solution shown in any one or more of the above examples, referring to FIG. 14, FIG. 14 illustrates a structural block diagram of a voltage generation circuit provided by an example of the present disclosure. As shown in FIG. 14, the second signal generation circuit 1001b comprises a low voltage generation sub-circuit 1001b1 and a clock signal generation sub-circuit 1001b2.

The low voltage generation sub-circuit 1001b1 is configured to take the source voltage signal as an input to output a voltage signal with a voltage amplitude greater than that of the source voltage signal to the clock signal generation sub-circuit 1001b2; and the clock signal generation sub-circuit 1001b2 is configured to take positive voltage sources of the low voltage generation sub-circuit 1001b1 and a voltage conversion circuit as input sources to output the first clock sub-signal and the second clock sub-signal.

In the examples of the present disclosure, the second signal generation circuit 1001b is divided into two portions, wherein the low voltage generation sub-circuit 1001b1 is configured to output a voltage signal (Vreq, such as 0.2 V) with a voltage amplitude greater than that of the source voltage signal (Vss, usually 0 V), and the clock signal generation sub-circuit 1001b2 takes the voltage signal as a low level signal and the voltage signal (Vsup) of the input positive voltage source as a high level signal to output two second clock signals (e.g., the first clock sub-signal and the second clock sub-signal described above) with complementary clock cycles, so as to achieve outputting of the clock signal generation with a higher low level voltage.

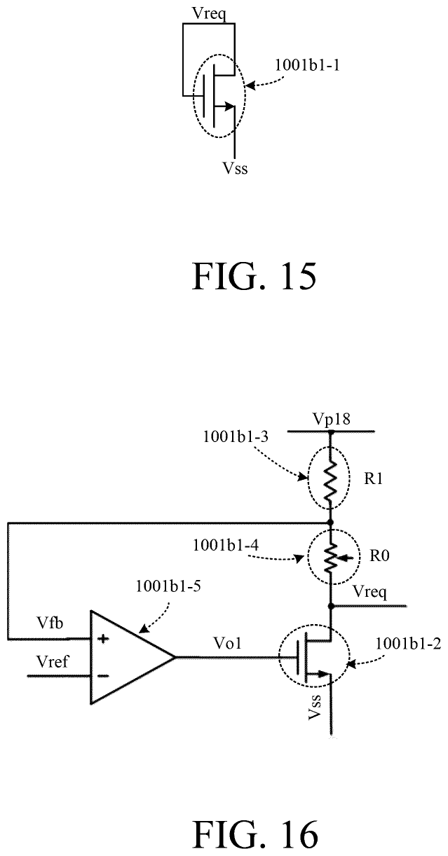

Based on the solution shown in FIG. 14 above, referring to FIG. 15, FIG. 15 illustrates a schematic structural diagram of a low voltage generation sub-circuit provided by examples of the present disclosure. As shown in FIG. 15, the low voltage generation sub-circuit 1001b1 comprises a third MOS transistor 1001b1-1 that is triggered to be turned on by a high level, wherein a first electrode and a third electrode of the third MOS transistor 1001b1-1 are connected with an output end of the third MOS transistor 1001b1-1, and a second electrode of the third MOS transistor 1001b1-1 is connected with a signal source of the source voltage signal, wherein a threshold voltage of the third MOS transistor 1001b1-1 is less than a voltage of the source voltage signal.

In the solution shown in the examples of the present disclosure, the above-mentioned third MOS transistor 1001b1-1 may be an NMOS transistor with a low threshold voltage. As shown in FIG. 14, in the event that the second electrode of the third MOS transistor 1001b1-1 inputs the source voltage signal (Vss), a voltage signal (a voltage value being Vreq, equal to the threshold voltage of the third MOS transistor 1001b1-1) with a voltage slightly higher than Vss may be generated between the first electrode and the third electrode of the third MOS transistor 1001b1-1. In an example, the above-mentioned first electrode may be a source, the second electrode is a drain, and the third electrode is a gate.

With the circuit structure shown in FIG. 14 above, a voltage signal with a voltage amplitude greater than that of the source voltage signal may be generated by a MOS transistor with a low threshold voltage, thereby ensuring that the circuit structure is simple and ensuring the generation efficiency of the voltage signal.

Based on the solution shown in FIG. 14 above, the low voltage generation sub-circuit may be also a linear regulator circuit.

For example, referring to FIG. 16, FIG. 16 illustrates a schematic structural diagram of another low voltage generation sub-circuit provided by examples of the present disclosure. As shown in FIG. 16, the linear regulator circuit (e.g., the above-mentioned low voltage generation sub-circuit 1001b1) comprises a fourth MOS transistor 1001b1-2, a fixed resistor 1001b1-3, an adjustable resistor 1001b1-4 and an amplifier 1001b1-5, wherein the fourth MOS transistor 1001b1-2 is triggered to be turned on by a high level; the fixed resistor 1001b1-3 and the adjustable resistor 1001b1-4 are connected in series between a pinch-off voltage source (Vp18) and a first electrode of the fourth MOS transistor 1001b1-2; a positive phase input end of the amplifier 1001b1-5 is connected between the fixed resistor 1001b1-3 and the adjustable resistor 1001b1-4, a negative phase input end of the amplifier 1001b1-5 is connected with a reference voltage source Vref, and an output end of the amplifier 1001b1-5 is connected with a third electrode of the fourth MOS transistor 1001b1-2; and a second electrode of the fourth MOS transistor 1001b1-2 is connected with a signal source of the source voltage signal (Vss).

As shown in FIG. 16, the fourth MOS transistor 1001b1-2 is triggered to be turned on by a voltage signal (Vo1) with a higher voltage value output by the amplifier 1001b1-5, and may output a voltage signal (Vreq) with a voltage value higher than Vss at the first electrode, and the voltage value of the voltage signal may be adjusted by the adjustable resistor 1001b1-4, such that the output adjustability and accuracy of the voltage signal can be ensured, and meanwhile, the requirements on the threshold voltage of the fourth MOS transistor 1001b1-2 are low.

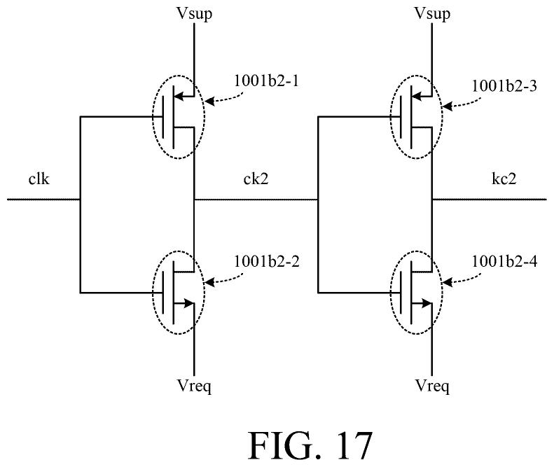

Based on the solution shown in any one or more examples corresponding to FIGS. 14 to 16 above, referring to FIG. 17, FIG. 17 illustrates a schematic structural diagram of the clock signal generation sub-circuit 1001b2 provided by an example of the present disclosure. As shown in FIG. 17, the clock signal generation sub-circuit 1001b2 comprises a fifth MOS transistor 1001b2-1, a sixth MOS transistor 1001b2-2, a seventh MOS transistor 1001b2-3 and an eighth MOS transistor 1001b2-4.

The fifth MOS transistor 1001b2-1 and the seventh MOS transistor 1001b2-3 are triggered to be turned on by a low level, and a first electrode of the fifth MOS transistor 1001b2-1 and a first electrode of the seventh MOS transistor 1001b2-3 are connected with a positive voltage source of the voltage conversion circuit. The sixth MOS transistor 1001b2-2 and the eighth MOS transistor 1001b2-4 are triggered to be turned on by a high level, and a second electrode of the sixth MOS transistor 1001b2-2 and a second electrode of the seventh MOS transistor 1001b2-3 are connected with a signal source of the source voltage signal; and a third electrode of the fifth MOS transistor 1001b2-1 and a third electrode of the sixth MOS transistor 1001b2-2 are connected with a clock signal input end. A second electrode of the fifth MOS transistor 1001b2-1 and a first electrode of the sixth MOS transistor 1001b2-2 are connected with a first output end of the clock signal generation sub-circuit 1001b2, a third electrode of the seventh MOS transistor 1001b2-3 and a third electrode of the eighth MOS transistor 1001b2-4 respectively. The second electrode of the seventh MOS transistor 1001b2-3 and a first electrode of the eighth MOS transistor 1001b2-4 are connected with a second output end of the clock signal generation sub-circuit 1001b2 respectively.

In an example, the fifth MOS transistor 1001b2-1 and the seventh MOS transistor 1001b2-3 described above may be PMOS transistors, the sixth MOS transistor 1001b2-2 and the eighth MOS transistor 1001b2-4 described above may be NMOS transistors, the above-mentioned first electrode may be a source of the MOS transistor, the second electrode may be a drain of the MOS transistor, and the third electrode may be a gate of the MOS transistor.

The first output end is configured to output the first clock sub-signal, and the second output end is configured to output the second clock sub-signal. Alternatively, the first output end is configured to output the second clock sub-signal, and the second output end is configured to output the first clock sub-signal.

For example, in FIG. 17, clock signals ck2 and kc2 are the first clock sub-signal and the second clock sub-signal respectively.

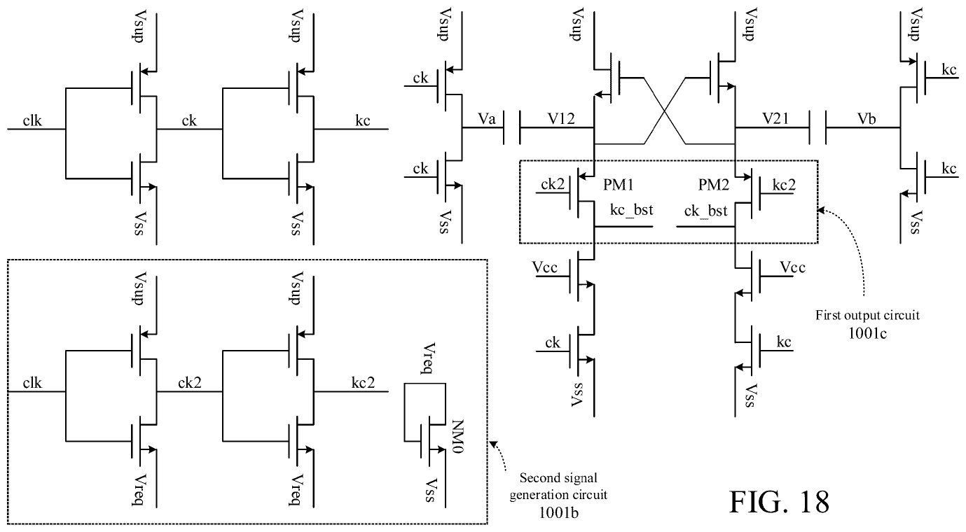

Based on the solution shown in any one or more of the above examples, referring to FIG. 18, FIG. 18 illustrates a schematic structural diagram of a clock voltage doubling circuit involved in the present disclosure. As shown in FIG. 18, the second signal generation circuit 1001b is at the bottom left corner, and MOS transistors PM1 and PM2 constitute the first output circuit 1001c. The remainder of FIG. 18 constitutes the first signal generation circuit 1001a, wherein the circuit structures of the first signal generation circuit 1001a and the first output circuit 1001c are similar to that of FIG. 7, which is no longer repeated herein. Different from FIG. 7, the second signal generation circuit 1001b is added in the clock voltage doubling circuit shown in FIG. 18, and clock signals of gates of the MOS transistors PM1 and PM2 are changed to the second clock signals (the clock signals ck2 and kc2) from the first clock signals (the clock signals ck and kc). In the circuit structure shown in FIG. 18, a position marked with “ck2” in the second signal generation circuit 1001b is a port outputting the clock signal ck2, a position marked with “ck2” in the first output circuit 1001c is a port inputting the clock signal ck2, and the position marked with “ck2” in the second signal generation circuit 1001b is connected with the position marked with “ck2” in the first output circuit 1001c. Correspondingly, a position marked with “kc2” in the second signal generation circuit 1001b is a port outputting the clock signal kc2, a position marked with “kc2” in the first output circuit 1001c is a port inputting the clock signal kc, and the position marked with “kc2” in the second signal generation circuit 1001b is connected with the position marked with “kc2” in the first output circuit 1001c.

In FIG. 18, voltages of low levels of the clock signals ck2 and kc2 are changed to Vreg from Vss. For example, the generation of Vreg using an NM0 transistor with a low threshold voltage in FIG. 18 is a simple generation way. In this case, the voltage Vreg is equal to the threshold voltage of NM0, and a very large NM0 is not required to generate Vreg since loads driven by the clock signals ck2 and kc2 are small. Furthermore, the circuit generating Vreg in FIG. 18 may be replaced with the linear regulator circuit shown in FIG. 16. In FIG. 16, Vref is a reference voltage, the voltage Vp18 may be 1.8 V, R1 is a resistor, R0 is an adjustable resistor, and a value of Vreg may be adjusted by adjusting R0. The voltage Vreg generated by the circuit structure shown in FIG. 16 is adjustable, and is less affected by Process-Voltage-Temperature (PVT). As shown in FIG. 18, when ck becomes Vss from Vsup, ck2 becomes Vreg from Vsup, and at this point, the transistor PM1 is turned on to transmit V12 to ck_bst. Since a voltage vg of the transistor PM1 becomes Vreg from Vss, the voltage withstanding problem of PM1 may be improved effectively when it is turned on, such that a voltage value of Vsup may be improved appropriately. Since PM1 and PM2 are both 3.3 V devices, their driving capability will not be reduced significantly when they are turned on using Vreg. Furthermore, in the event that Vreg is generated using the circuit shown in FIG. 16, its value may be adjusted flexibly, and thus, the voltage values of Vreg and Vsup may be adjusted flexibly according to actual voltage withstanding situation.

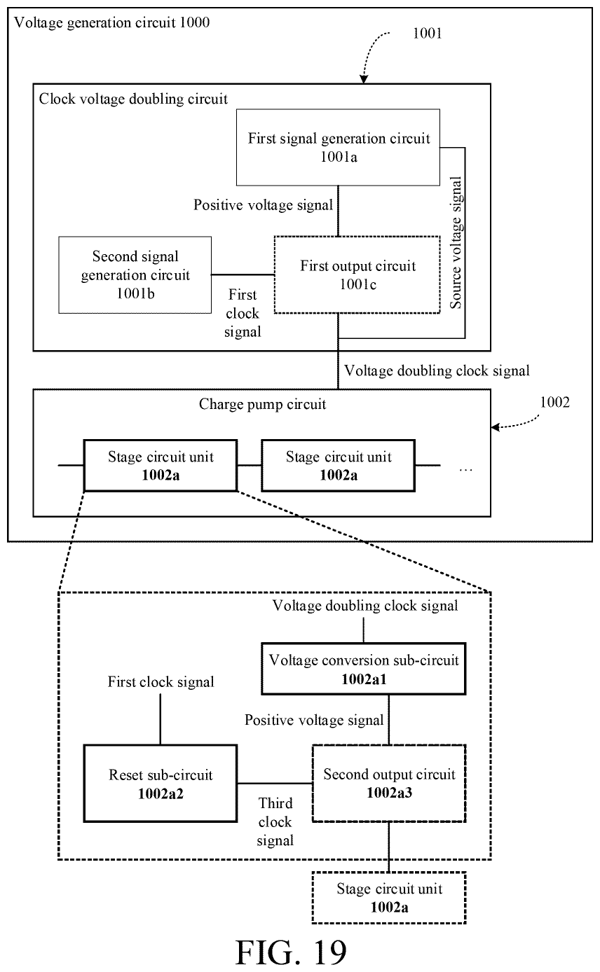

Based on the solution shown in any one or more of the above examples, referring to FIG. 19, FIG. 19 illustrates a schematic structural diagram of another voltage generation circuit involved in the present disclosure. As shown in FIG. 19, the charge pump circuit 1002 comprises at least one stage circuit unit 1002a that comprises a voltage conversion sub-circuit 1002a1, a reset sub-circuit 1002a2 and a second output circuit 1002a3.

The voltage conversion sub-circuit 1002a1 is connected with a first electrode of a MOS transistor in the second output circuit and is configured to output a converted positive voltage signal to the first electrode of the MOS transistor in the second output circuit under the control of the voltage doubling clock signal. The reset sub-circuit 1002a2 is connected with a third electrode of the MOS transistor in the second output circuit and an output end of the charge pump circuit, and is configured to output a third clock signal to the third electrode of the MOS transistor in the second output circuit, wherein the MOS transistor in the second output circuit is configured to be turned on when the third clock signal is at a low level, and a voltage of the third clock signal at the low level is greater than a voltage of the source voltage signal.

The MOS transistor in the above-mentioned second output circuit may be a PMOS transistor or other MOS transistors that are turned on by a low level. In an example, the above-mentioned first electrode may be a source in the MOS transistor, the second electrode may be a drain in the MOS transistor, and the third electrode may be a gate in the MOS transistor.

In the examples of the present disclosure, for the MOS transistor in the charge pump circuit for signal output, a clock signal with a low level voltage greater than that of the source voltage signal is configured to control turn-on as well, such that a gate on voltage of the MOS transistor of the output circuit in the charge pump circuit may be increased appropriately, and a voltage value of the positive voltage signal input by the source of the MOS transistor may be increased appropriately, thereby ensuring the efficiency of the charge pump circuit.

Based on the example shown in FIG. 19 above, the above-mentioned reset sub-circuit 1002a2 is configured to output the third clock signal to the third electrode of the MOS transistor in the second output circuit 1002a3 under the driving of the first clock signal; the first clock signal comprises a third clock sub-signal and a fourth clock sub-signal; and the third clock sub-signal and the fourth clock sub-signal are the same in cycle, level states of the third clock sub-signal and the first clock sub-signal at the same instant are the same, and level states of the third clock sub-signal and the fourth clock sub-signal at the same instant are opposite.

The third clock sub-signal and the fourth clock sub-signal described above may be clock signals with complementary clock cycles, and a level relation between the third clock sub-signal and the fourth clock sub-signal may be referred to a relation between the clock signals ck and kc in FIG. 8.

In a possible implementation, voltages of the third clock sub-signal and the fourth clock sub-signal at a high level are the same as a voltage of a positive voltage source of the voltage conversion circuit, and voltages of the third clock sub-signal and the fourth clock sub-signal at a low level are the same as the voltage of the source voltage signal.

For example, the voltages of the third clock sub-signal and the fourth clock sub-signal described above may be Vsup at the high level, and Vss at the low level.

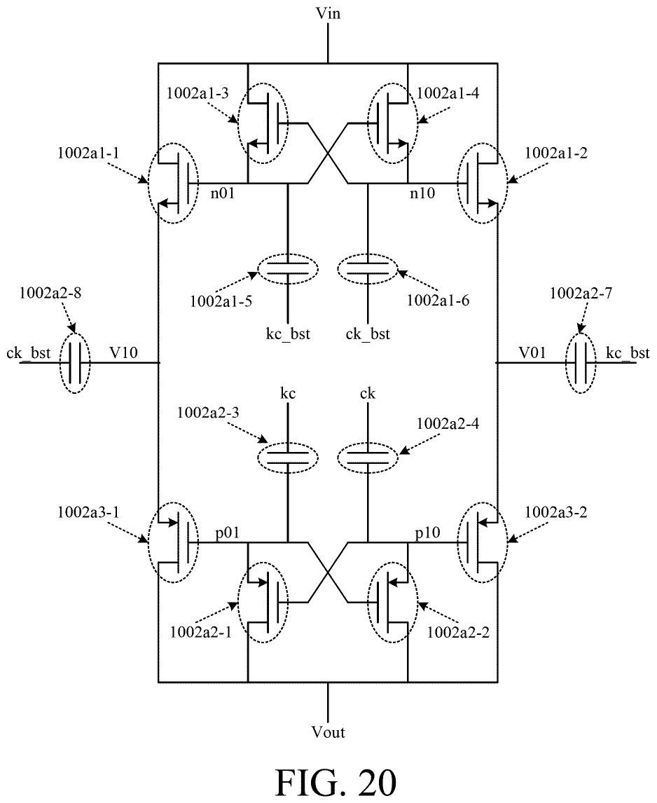

Based on the examples shown in FIG. 19 above, referring to FIG. 20, FIG. 20 illustrates a schematic structural diagram of a stage circuit unit involved in the present disclosure. As shown in FIG. 20, in the above-mentioned stage circuit unit 1002a, the second output circuit 1002a3 comprises a ninth MOS transistor 1002a3-1 and a tenth MOS transistor 1002a3-2, and the reset sub-circuit 1002a2 comprises an eleventh MOS transistor 1002a2-1, a twelfth MOS transistor 1002a2-2, a first capacitor 1002a2-3 and a second capacitor 1002a2-4, wherein the ninth MOS transistor 1002a3-1, the tenth MOS transistor 1002a3-2, the eleventh MOS transistor 1002a2-1, and the twelfth MOS transistor 1002a2-2 are triggered to be turned on by a low level.

The third clock sub-signal is input by an end of the first capacitor 1002a2-3, and the other end of the first capacitor 1002a2-3 is connected with a third electrode of the ninth MOS transistor 1002a3-1, a first electrode of the eleventh MOS transistor 1002a2-1 and a third electrode of the twelfth MOS transistor 1002a2-2. The fourth clock sub-signal is input by an end of the second capacitor 1002a2-4, and the other end of the second capacitor 1002a2-4 is connected with a third electrode of the tenth MOS transistor 1002a3-2, a first electrode of the twelfth MOS transistor 1002a2-2 and a third electrode of the eleventh MOS transistor 1002a2-1. A second electrode of the ninth MOS transistor 1002a3-1, a second electrode of the tenth MOS transistor 1002a3-2, a second electrode of the eleventh MOS transistor 1002a2-1 and a second electrode of the twelfth MOS transistor 1002a2-2 are connected with a voltage output end (Vout) of the stage circuit unit 1002a.

The voltage conversion sub-circuit 1002a1 is configured to apply a converted positive voltage signal to a first electrode of the ninth MOS transistor 1002a3-1 when the third clock sub-signal is at a low level, and to apply the converted positive voltage signal to a first electrode of the tenth MOS transistor 1002a3-2 when the fourth clock sub-signal is at a low level.

For example, the ninth MOS transistor 1002a3-1, the tenth MOS transistor 1002a3-2, the eleventh MOS transistor 1002a2-1 and the twelfth MOS transistor 1002a2-2 described above may be PMOS transistors, or other MOS transistors turned on by a low level.

The above-mentioned first electrode may be a source of the MOS transistor, the second electrode may be a drain of the MOS transistor, and the third electrode may be a gate of the MOS transistor. Alternatively, the above-mentioned first electrode may be a drain of the MOS transistor, the second electrode may be a source of the MOS transistor, and the third electrode may be a gate of the MOS transistor.

In some examples, the voltage doubling clock signal comprises a fifth clock sub-signal and a sixth clock sub-signal that are the same in cycle, wherein level states of the fifth clock sub-signal and the first clock sub-signal at the same instant are the same, and level states of the fifth clock sub-signal and the sixth clock sub-signal at the same instant are opposite.

The fifth clock sub-signal and the sixth clock sub-signal in the voltage doubling clock signal may be referred to the clock signal 1303 and the clock signal 1304 in FIG. 13, which is no longer repeated herein.

With reference to FIG. 20, the voltage conversion sub-circuit 1002a1 comprises a thirteenth MOS transistor 1002a1-1, a fourteenth MOS transistor 1002a1-2, a fifteenth MOS transistor 1002a1-3, a sixteenth MOS transistor 1002a1-4, a third capacitor 1002a1-5, a fourth capacitor 1002a1-6, a fifth capacitor 1002a1-7 and a sixth capacitor 1002a1-8, wherein the thirteenth MOS transistor 1002a1-1, the fourteenth MOS transistor 1002a1-2, the fifteenth MOS transistor 1002a1-3 and the sixteenth MOS transistor 1002a1-4 are triggered to be turned on by a high level.

The fifth clock sub-signal is input by an end of the third capacitor 1002a1-5 and an end of the fifth capacitor 1002a1-7, and the other end of the third capacitor 1002a1-5 is connected with a third electrode of the thirteenth MOS transistor 1002a1-1, a second electrode of the fifteenth MOS transistor 1002a1-3 and a third electrode of the sixteenth MOS transistor 1002a1-4.

The sixth clock sub-signal is input by an end of the fourth capacitor 1002a1-6 and an end of the sixth capacitor 1002a1-8, and the other end of the fourth capacitor 1002a1-6 is connected with a third electrode of the fourteenth MOS transistor 1002a1-2, a second electrode of the sixteenth MOS transistor 1002a1-4 and a third electrode of the fifteenth MOS transistor 1002a1-3.

A first electrode of the thirteenth MOS transistor 1002a1-1, a first electrode of the fourteenth MOS transistor 1002a1-2, a first electrode of the fifteenth MOS transistor 1002a1-3 and a first electrode of the sixteenth MOS transistor 1002a1-4 are connected with a voltage input end (Vin) of the stage circuit unit.

The other end of the fifth capacitor 1002a1-7 is connected with a second electrode of the fourteenth MOS transistor 1002a1-2 and a first electrode of the tenth MOS transistor 1002a3-2; and the other end of the sixth capacitor is connected with a second electrode of the thirteenth MOS transistor 1002a1-1 and a first electrode of the ninth MOS transistor 1002a3-1.

As shown in FIG. 20, for the voltage withstanding problem possibly existing in the PMOS transistor in the charge pump stage circuit, examples of the present disclosure also propose a new stage circuit structure. As shown in FIG. 20, the improved charge pump stage circuit and the structure shown in FIG. 9 differs in that an input NMOS transistor and an output PMOS transistor are controlled separately in the charge pump stage circuit shown in FIG. 20, wherein a clock signal ck_bst/kc_bst controlling the PMOS transistor is replaced with ck/kc, and reset circuits of p01 and p10 are added at the same time. When ck_bst is at a high level, kc is at a low level, and p01 is pulled down to Vout minus an amplitude of one kc clock, such that the transistor PM1 (the ninth MOS transistor 1002a3-1 in FIG. 20) is turned on to transmit V10 to Vout. Similarly, when ck_bst is at a low level, kc is at a high level, and the p01 level is raised, and at this point, p10 is Vout minus an amplitude of one ck clock, such that p01 is reset to the Vout level. At this point, the transistor PM1 is turned off, and the transistor PM2 (the tenth MOS transistor 1002a3-2 in FIG. 20) is turned on to transmit V01 to Vout. Since the voltage withstanding of Vgs of the PMOS transistor is changed from an amplitude of ck_bst to an amplitude of ck when it is turned on, the voltage withstanding problem can be avoided effectively when the PMOS transistor is turned on, and meanwhile, the amplitude of one ck clock is enough to turn on the low voltage PMOS transistor to transmit V10/V01 to Vout. Therefore, no obvious influence will be caused to the driving capability of the charge pump. Simulation results show that the clock voltage doubling circuit and the charge pump stage circuit using the new structures shown in FIGS. 18 and 20 may effectively improve the voltage withstanding problem of the PMOS transistor when it is turned on, and meanwhile, the influence on the driving capability and efficiency at the same voltage Vsup is almost negligible. Moreover, the clock voltage doubling circuit and the charge pump stage circuit of new structures proposed by the present disclosure can increase the voltage Vsup, and thus, the driving capability and efficiency of the charge pump can be improved.

For example, when the temperature is 25° C., Vcc=2.5 V, and Vout=6 V at some test point, for the clock voltage doubling circuit and the charge pump stage circuit using the structures shown in FIGS. 18 and 20, compared with the clock voltage doubling circuit and the charge pump stage circuit using the structures shown in FIGS. 7 and 9, the driving capability of the charge pump and the voltage withstanding capability of the PMOS transistor are improved. In an example, in the event that Vsup=2.25 V, an output current may be increased to 0.2 mA, the power supply efficiency may be increased by about 1%, the maximum PMOS Vgs of the clock voltage doubling circuit may be increased by about 0.3 V, and the maximum PMOS Vgs of the charge pump circuit is substantially equivalent. In the event that Vsup=2.5V, the maximum PMOS Vgs of the clock voltage doubling circuit and the charge pump circuit may be increased by about 0.3 V respectively, while the output current and the power supply efficiency are substantially equivalent. As can be seen, due to the SOA problem of the PMOS transistor, a maximum voltage limit of Vsup used by the structures shown in FIGS. 7 and 9 is 2.25 V, while with the clock voltage doubling circuit and the charge pump circuit of new structures (for example, the structures shown in FIGS. 18 and 2) proposed in the present disclosure, the voltage Vsup may be increased to 2.5 V, thereby improving the driving capability and efficiency of the charge pump. Meanwhile, when Vsup=2.25 V, compared with the structures shown in FIGS. 7 and 9, various indicators of the clock voltage doubling circuit and the charge pump circuit of the new structures proposed in the present disclosure are not deteriorated and are even improved slightly.

The clock voltage doubling circuit and the charge pump circuit of the new structures provided by the above-mentioned examples of the present disclosure employ an adjustable clock amplitude technology, the solution is simple, and the amplitude of the clock signal is adjustable. The above solution separates a control clock of the voltage withstanding PMOS transistor in the clock voltage doubling circuit, employs an amplitude-adjustable clock, reduces VGS voltage withstanding when the PMOS transistor is turned on, and improves the SOA problem. Furthermore, the above solution also separates control clocks of the input NMOS transistor and the output PMOS transistor in the charge pump circuit, reduces a clock amplitude of the output PMOS transistor, reduces the VGS withstanding when the PMOS transistor is turned on, and improves the SOA problem.

For the clock voltage doubling circuit and the charge pump circuit of the new structures provided by the above examples of the present disclosure, an output clock amplitude of the clock voltage doubling circuit can be increased, and the driving capability and efficiency of the charge pump can be improved. Meanwhile, compared with the original circuit structure, the increased area is small, the solution is simple to control, no new problem is introduced, and the SOA problem of the low voltage PMOS transistor in the charge pump at the current process node can be improved.

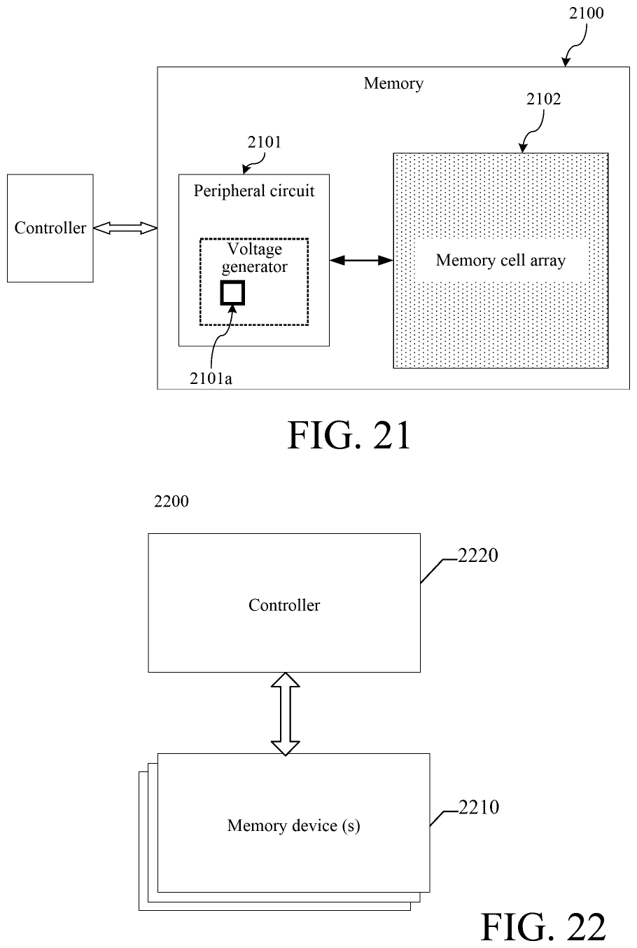

FIG. 21 is a structural block diagram of a memory device provided by an example of the present disclosure. As shown in FIG. 21, the memory device 2100 comprises a peripheral circuit 2101 and a memory cell array 2102, wherein the peripheral circuit 2101 comprises one or more voltage generation circuits 2101a. The above-mentioned voltage generation circuit 2101a may be the voltage generation circuit 1000 involved in the above examples.

In the examples of the present disclosure, the voltage generation circuit 1000 shown in FIG. 10 above may be implemented as part of the voltage generator in the memory device. For example, a voltage generator in the memory device may use an external supply voltage or an internal supply voltage to generate various voltages, for example, a program voltage, a read voltage, a pass voltage, a verify voltage, a bit line voltage, etc., and a combination thereof, required by the memory device based on the above-mentioned voltage generation circuit 1000.

FIG. 22 is a structural block diagram of a memory system provided by an example of the present disclosure. As shown in FIG. 22, the memory system 2200 comprises: one or more memory devices 2210; and
a controller 2220 coupled to the memory devices 2210 and configured to control the memory devices 2210.

The memory system 2200 may be all or part of a mobile phone, a desktop computer, a laptop computer, a tablet computer, a vehicle computer, a gaming console, a printer, a positioning device, a wearable electronic device, a smart sensor, a Virtual Reality (VR) device, an Augmented Reality (AR) device, or any other suitable electronic devices having memory devices therein.

In an example, the memory system 2200 may comprise a host and a memory sub-system, wherein the memory sub-system has one or more memory devices 2210 and a controller 2220. The host may be a processor of an electronic device (e.g., a central processing unit (CPU), or a system on chip (SoC) (e.g., an disclosure processor (AP))). The host may be configured to send data to the memory device 2210. Alternatively, the host may be configured to receive data from the memory device 2210.

According to some implementations, the controller 2220 is further coupled to the host. The controller 2220 may manage data stored in the memory device 2210, and communicate with the host.

In some implementations, the controller 2220 is designed for operating in a low duty-cycle environment, such as secure digital (SD) cards, compact flash (CF) cards, universal serial bus (USB) flash drives, or other media for use in electronic devices, such as personal computers, digital cameras, mobile phones, etc.

In some implementations, the controller 2220 is designed for operating in high duty-cycle environment solid-state disks (SSD) or embedded multi-media cards (eMMC) configured as data memory devices for mobile devices, such as smartphones, tablets, laptop computers, etc., and enterprise memory arrays.

The controller 2220 may be configured to control operations of the memory device 2210, such as read, erase, and program operations. The controller 2220 may be further configured to manage various functions with respect to data stored or to be stored in the memory device 2210, including, but not limited to, bad-block management, garbage collection, logical-to-physical address conversion, wear leveling, etc. In some implementations, the controller 2220 is further configured to process error correction codes (ECCs) with respect to the data read from or written to the memory device 2210.

The controller 2220 may further perform any other suitable functions, for example, format the memory device 2210. The controller 2220 may communicate with an external device according to a particular communication protocol.

The controller 2220 and the one or more memory devices 2210 may be integrated into various types of memory apparatuses, for example, be included in the same package (such as a universal flash storage (UFS) package or an eMMC package). That is to say, the memory system 2200 may be implemented and packaged into different types of end electronic products.

In an example, the controller 2220 and a single memory device 2210 may be integrated into a memory card. The memory card may include a PC card (Personal Computer Memory Card International Association (PCMCIA)), a CF card, a smart media (SM) card, a memory stick, a multimedia card (MMC, RS-MMC, MMCmicro), an SD card (SD, miniSD, microSD, SDHC), a UFS, etc. The memory card may further comprise a memory card connector coupling the memory card with the host.

In an example, the controller 2220 and a plurality of memory devices 2210 may be integrated into a solid state drive (SSD). In some implementations, the memory capacity and/or operation speed of the solid state drive are greater than those of the memory card.

The above-mentioned memory device 2210 may be implemented as the memory device 100 in the examples shown in any one of FIGS. 1 to 3, and the above-mentioned controller 2220 may be implemented as the controller 200 in the examples shown in any one of FIGS. 1 to 3.

In the examples of the present disclosure, the above-mentioned memory device 2210 comprises a peripheral circuit and a memory cell array, wherein the peripheral circuit comprises one or more voltage generation circuits. In an example, the voltage generation circuits may be disposed in a voltage generator of the memory device. The above-mentioned voltage generation circuit 2101a may be the voltage generation circuit 1000 involved in the above examples.

In the present disclosure, the terms “first” and “second” are for descriptive purposes only, and cannot be construed as indicating or implying relative importance. The term “at least one” means one or more, and the term “a plurality of” means two or more, unless otherwise defined clearly.

The term “and/or” in the present disclosure is merely an association relationship describing related objects, which means that there may be three relationships, for example, A and/or B may indicate three cases: A exists alone, A and B exist simultaneously, and B exists alone. In addition, the character “/” herein generally indicates that the related objects are in an “or” relationship.

The above are only examples of the present disclosure, and are not employed to limit the present disclosure. Any modifications, equivalent replacements and improvements and the like made within the spirit and principle of the present disclosure shall be included within the scope of protection of the present disclosure.

What is claimed is:

1. A voltage generation circuit comprising:
a clock voltage doubling circuit comprising a first signal generation circuit, a second signal generation circuit and a first output circuit; and
a charge pump circuit, wherein:
the first signal generation circuit is connected with a first electrode and a second electrode of a metal oxide semiconductor (MOS) transistor in the first output circuit, the second signal generation circuit is connected with a third electrode of the MOS transistor in the first output circuit, and the second electrode of the MOS transistor in the first output circuit is connected with the charge pump circuit;
the first signal generation circuit is configured to apply a positive voltage signal to the first electrode of the MOS transistor in the first output circuit and apply a source voltage signal to the second electrode of the MOS transistor in the first output circuit under control of an input first clock signal;
the second signal generation circuit is configured to apply a second clock signal different from the input first clock signal to the third electrode of the MOS transistor in the first output circuit under the control of the input first clock signal; and
the first output circuit is configured to output a voltage doubling clock signal to the charge pump circuit under control of the second clock signal.

2. The voltage generation circuit of claim 1, wherein a high level voltage of the voltage doubling clock signal is the same as a voltage of the positive voltage signal, and a low level voltage of the voltage doubling clock signal is the same as a voltage of the source voltage signal.

3. The voltage generation circuit of claim 1, wherein a first port of the first signal generation circuit is connected with the first electrode of the MOS transistor in the first output circuit, and a second port of the first signal generation circuit is connected with the second electrode of the MOS transistor in the first output circuit;
the MOS transistor in the first output circuit is configured to:
output a high level voltage of the voltage doubling clock signal through the second electrode of the MOS transistor in the first output circuit when the second clock signal applied to the third electrode of the MOS transistor in the first output circuit is at a low level; and
output a low level voltage of the voltage doubling clock signal through the second electrode of the MOS transistor in the first output circuit when the second clock signal applied to the third electrode of the MOS transistor in the first output circuit is at a high level; and
wherein a voltage of the second clock signal at the low level is greater than a voltage of the source voltage signal.

4. The voltage generation circuit of claim 3, wherein the first output circuit comprises a first MOS transistor and a second MOS transistor;
the second clock signal comprises a first clock sub-signal and a second clock sub-signal;
the second signal generation circuit is configured to apply the first clock sub-signal to a third electrode of the first MOS transistor and apply the second clock sub-signal to a third electrode of the second MOS transistor; and
wherein the first clock sub-signal and the second clock sub-signal are the same in cycle, and level states of the first clock sub-signal and the second clock sub-signal at a same instant are opposite.

5. The voltage generation circuit of claim 4, wherein the second signal generation circuit comprises:
a low voltage generation sub-circuit configured to take the source voltage signal as an input to output a voltage signal with a voltage amplitude greater than that of the source voltage signal to a clock signal generation sub-circuit; and
the clock signal generation sub-circuit configured to take the low voltage generation sub-circuit and a positive voltage source of a voltage conversion circuit as input sources to output the first clock sub-signal and the second clock sub-signal.

6. The voltage generation circuit of claim 5, wherein the low voltage generation sub-circuit comprises a third MOS transistor that is triggered to be turned on by a high level,
wherein a first electrode and a third electrode of the third MOS transistor are connected with an output end of the third MOS transistor, and a second electrode of the third MOS transistor is connected with a signal source of the source voltage signal; and
a threshold voltage of the third MOS transistor is less than the voltage of the source voltage signal.

7. The voltage generation circuit of claim 5, wherein the low voltage generation sub-circuit is a linear regulator circuit.

8. The voltage generation circuit of claim 7, wherein the linear regulator circuit comprises a fourth MOS transistor, a fixed resistor, an adjustable resistor and an amplifier, wherein the fourth MOS transistor is triggered to be turned on by a high level;
the fixed resistor and the adjustable resistor are connected in series between a pinch-off voltage source and a first electrode of the fourth MOS transistor;
a positive phase input end of the amplifier is connected between the fixed resistor and the adjustable resistor, a negative phase input end of the amplifier is connected with a reference voltage source, and an output end of the amplifier is connected with a third electrode of the fourth MOS transistor; and
a second electrode of the fourth MOS transistor is connected with a signal source of the source voltage signal.

9. The voltage generation circuit of claim 5, wherein the clock signal generation sub-circuit comprises a fifth MOS transistor, a sixth MOS transistor, a seventh MOS transistor and an eighth MOS transistor;
the fifth MOS transistor and the seventh MOS transistor are triggered to be turned on by a low level, and a first electrode of the fifth MOS transistor and a first electrode of the seventh MOS transistor are connected with the positive voltage source of the voltage conversion circuit respectively;
the sixth MOS transistor and the eighth MOS transistor are triggered to be turned on by a high level, and a second electrode of the sixth MOS transistor and a second electrode of the seventh MOS transistor are connected with a signal source of the source voltage signal respectively;
a third electrode of the fifth MOS transistor and a third electrode of the sixth MOS transistor are connected with a clock signal input end respectively;
a second electrode of the fifth MOS transistor and a first electrode of the sixth MOS transistor are connected with a first output end of the clock signal generation sub-circuit, a third electrode of the seventh MOS transistor and a third electrode of the eighth MOS transistor respectively; and
the second electrode of the seventh MOS transistor and a first electrode of the eighth MOS transistor are connected with a second output end of the clock signal generation sub-circuit,
wherein the first output end is configured to output the first clock sub-signal, and the second output end is configured to output the second clock sub-signal; or the first output end is configured to output the second clock sub-signal, and the second output end is configured to output the first clock sub-signal.

10. The voltage generation circuit of claim 4, wherein the charge pump circuit comprises at least one stage circuit unit comprising:
a second output circuit;
a voltage conversion sub-circuit connected with a first electrode of a MOS transistor in the second output circuit, and configured to output a converted positive voltage signal to the first electrode of the MOS transistor in the second output circuit under the control of the voltage doubling clock signal;
a reset sub-circuit connected with a third electrode of the MOS transistor in the second output circuit and an output end of the charge pump circuit, and configured to output a third clock signal to the third electrode of the MOS transistor in the second output circuit; and
wherein the MOS transistor in the second output circuit is configured to be turned on when the third clock signal is at a low level, and a voltage of the third clock signal at the low level is greater than the voltage of the source voltage signal.

11. The voltage generation circuit of claim 10, wherein the reset sub-circuit is configured to output the third clock signal to the third electrode of the MOS transistor in the second output circuit under driving of the input first clock signal;
the input first clock signal comprises a third clock sub-signal and a fourth clock sub-signal; and
the third clock sub-signal and the fourth clock sub-signal are the same in cycle, level states of the third clock sub-signal and the first clock sub-signal at a same instant are the same, and level states of the third clock sub-signal and the fourth clock sub-signal at the same instant are opposite.

12. The voltage generation circuit of claim 11, wherein voltages of the third clock sub-signal and the fourth clock sub-signal at a high level are the same as a voltage of a positive voltage source of the voltage conversion sub-circuit, and voltages of the third clock sub-signal and the fourth clock sub-signal at a low level are the same as the voltage of the source voltage signal.

13. The voltage generation circuit of claim 11, wherein
the second output circuit comprises a ninth MOS transistor and a tenth MOS transistor, and the reset sub-circuit comprises an eleventh MOS transistor, a twelfth MOS transistor, a first capacitor and a second capacitor, wherein the ninth MOS transistor, the tenth MOS transistor, the eleventh MOS transistor, and the twelfth MOS transistor are triggered to be turned on by a low level;
the third clock sub-signal is input by an end of the first capacitor, and another end of the first capacitor is connected with a third electrode of the ninth MOS transistor, a first electrode of the eleventh MOS transistor and a third electrode of the twelfth MOS transistor respectively;
the fourth clock sub-signal is input by an end of the second capacitor, and another end of the second capacitor is connected with a third electrode of the tenth MOS transistor, a first electrode of the twelfth MOS transistor and a third electrode of the eleventh MOS transistor respectively;
a second electrode of the ninth MOS transistor, a second electrode of the tenth MOS transistor, a second electrode of the eleventh MOS transistor and a second electrode of the twelfth MOS transistor are connected with a voltage output end of the stage circuit unit respectively; and
the voltage conversion sub-circuit is configured to apply a converted positive voltage signal to a first electrode of the ninth MOS transistor when the third clock sub-signal is at a low level, and to apply the converted positive voltage signal to a first electrode of the tenth MOS transistor when the fourth clock sub-signal is at a low level.

14. The voltage generation circuit of claim 13, wherein the voltage doubling clock signal comprises a fifth clock sub-signal and a sixth clock sub-signal that are the same in cycle, wherein level states of the fifth clock sub-signal and the first clock sub-signal at the same instant are the same, and level states of the fifth clock sub-signal and the sixth clock sub-signal at the same instant are opposite;
the voltage conversion sub-circuit comprises a thirteenth MOS transistor, a fourteenth MOS transistor, a fifteenth MOS transistor, a sixteenth MOS transistor, a third capacitor, a fourth capacitor, a fifth capacitor and a sixth capacitor, wherein the thirteenth MOS transistor, the fourteenth MOS transistor, the fifteenth MOS transistor and the sixteenth MOS transistor are triggered to be turned on by a high level;
the fifth clock sub-signal is input by an end of the third capacitor and an end of the fifth capacitor, and another end of the third capacitor is connected with a third electrode of the thirteenth MOS transistor, a second electrode of the fifteenth MOS transistor and a third electrode of the sixteenth MOS transistor respectively;
the sixth clock sub-signal is input by an end of the fourth capacitor and an end of the sixth capacitor, and another end of the fourth capacitor is connected with a third electrode of the fourteenth MOS transistor, a second electrode of the sixteenth MOS transistor and a third electrode of the fifteenth MOS transistor respectively;
a first electrode of the thirteenth MOS transistor, a first electrode of the fourteenth MOS transistor, a first electrode of the fifteenth MOS transistor and a first electrode of the sixteenth MOS transistor are connected with a voltage input end of the stage circuit unit respectively; and
another end of the fifth capacitor is connected with a second electrode of the thirteenth MOS transistor and the first electrode of the ninth MOS transistor respectively; and another end of the sixth capacitor is connected with a second electrode of the fourteenth MOS transistor and the first electrode of the tenth MOS transistor respectively.

15. A memory device, comprising:
a memory cell array; and
a peripheral circuit coupled to the memory cell array, the peripheral circuit comprises one or more voltage generation circuits, each of the voltage generation circuits comprising:
a clock voltage doubling circuit comprising a first signal generation circuit, a second signal generation circuit and a first output circuit; and
a charge pump circuit, wherein:
the first signal generation circuit is connected with a first electrode and a second electrode of a metal oxide semiconductor (MOS) transistor in the first output circuit, the second signal generation circuit is connected with a third electrode of the MOS transistor in the first output circuit, and the second electrode of the MOS transistor in the first output circuit is connected with the charge pump circuit;
the first signal generation circuit is configured to apply a positive voltage signal to the first electrode of the MOS transistor in the first output circuit and apply a source voltage signal to the second electrode of the MOS transistor in the first output circuit under control of an input first clock signal;
the second signal generation circuit is configured to apply a second clock signal different from the input first clock signal to the third electrode of the MOS transistor in the first output circuit under the control of the input first clock signal; and
the first output circuit is configured to output a voltage doubling clock signal to the charge pump circuit under control of the second clock signal.

16. A memory system, comprising:
one or more memory devices; and
a controller coupled to the memory devices and configured to control the memory devices, wherein:
each of the memory devices comprises:
a memory cell array; and
a peripheral circuit comprising one or more voltage generation circuits, each of the voltage generation circuits comprising:
a clock voltage doubling circuit comprising a first signal generation circuit, a second signal generation circuit and a first output circuit; and
a charge pump circuit, wherein:
the first signal generation circuit is connected with a first electrode and a second electrode of a metal oxide semiconductor (MOS) transistor in the first output circuit, the second signal generation circuit is connected with a third electrode of the MOS transistor in the first output circuit, and the second electrode of the MOS transistor in the first output circuit is connected with the charge pump circuit;
the first signal generation circuit is configured to apply a positive voltage signal to the first electrode of the MOS transistor in the first output circuit and apply a source voltage signal to the second electrode of the MOS transistor in the first output circuit under the control of an input first clock signal;
the second signal generation circuit is configured to apply a second clock signal different from the input first clock signal to the third electrode of the MOS transistor in the first output circuit under the control of the input first clock signal; and
the first output circuit is configured to output a voltage doubling clock signal to the charge pump circuit under the control of the second clock signal.

17. The system of claim 16, wherein a first port of the first signal generation circuit is connected with the first electrode of the MOS transistor in the first output circuit, and a second port of the first signal generation circuit is connected with the second electrode of the MOS transistor in the first output circuit;
the MOS transistor in the first output circuit is configured to:
output a high level voltage of the voltage doubling clock signal through the second electrode of the MOS transistor in the first output circuit when the second clock signal applied to the third electrode of the MOS transistor in the first output circuit is at a low level; and
output a low level voltage of the voltage doubling clock signal through the second electrode of the MOS transistor in the first output circuit when the second clock signal applied to the third electrode of the MOS transistor in the first output circuit is at a high level; and
wherein a voltage of the second clock signal at the low level is greater than a voltage of the source voltage signal.

18. The system of claim 17, wherein the first output circuit comprises a first MOS transistor and a second MOS transistor;
the second clock signal comprises a first clock sub-signal and a second clock sub-signal;
the second signal generation circuit is configured to apply the first clock sub-signal to a third electrode of the first MOS transistor and apply the second clock sub-signal to a third electrode of the second MOS transistor; and
wherein the first clock sub-signal and the second clock sub-signal are the same in cycle, and level states of the first clock sub-signal and the second clock sub-signal at a same instant are opposite.

19. The system of claim 18, wherein the second signal generation circuit comprises:
a low voltage generation sub-circuit configured to take the source voltage signal as an input to output a voltage signal with a voltage amplitude greater than that of the source voltage signal to a clock signal generation sub-circuit; and
the clock signal generation sub-circuit configured to take the low voltage generation sub-circuit and a positive voltage source of a voltage conversion circuit as input sources to output the first clock sub-signal and the second clock sub-signal.

20. The system of claim 19, wherein the low voltage generation sub-circuit comprises a third MOS transistor that is triggered to be turned on by a high level,
wherein a first electrode and a third electrode of the third MOS transistor are connected with an output end of the third MOS transistor, and a second electrode of the third MOS transistor is connected with a signal source of the source voltage signal; and
a threshold voltage of the third MOS transistor is less than the voltage of the source voltage signal.
